(19) United States
(12) Patent Application Publication
(10) Pub. No.: US 2014/0217608 A1
(43) Pub. Date: Aug. 7, 2014

(54) SEMICONDUCTOR MODULE, CIRCUIT BOARD

(71) Applicant: Yasushi Takayama, Niwa-gun (JP)

(72) Inventor: Yasushi Takayama, Niwa-gun (JP)

(73) Assignee: NGK SPARK PLUG CO., LTD., Nagoya-shi, Aichi-ken (JP)

(21) Appl. No.: 14/239,479

(22) PCT Filed: Sep. 6, 2012
(86) PCT No.: PCT/JP12/05668

§ 371 Date: Feb. 18, 2014

(30) Foreign Application Priority Data
Sep. 9, 2011 (JP) 2011-197069
Mar. 19, 2012 (JP) 2012-061826
Mar. 19, 2012 (JP) 2012-061846

(51) Int. Cl. H01L 23/48; H05K 1/18

(52) U.S. Cl. CPC H01L 23/481; H05K 1/182; H05K 2201/10431
USPC 257/774; 174/266

(57) ABSTRACT

An improvement in the manufacturing efficiency of a circuit substrate and a semiconductor module where a semiconductor device including electrodes on a front and a back surface is mounted.

[Solution] A semiconductor module includes a wiring substrate where a via and a interconnecting pattern are formed, a semiconductor device disposed on a first surface side of the wiring substrate, and a bonding portion including a first bonding layer disposed on the wiring substrate side and a second bonding layer disposed on the semiconductor device side. The first bonding layer includes a first insulation layer having inorganic material as the main constituent, a through hole formed in an area of the first insulation layer corresponding to the via, and a conductive bonding portion, disposed in the through hole, for establishing electrical continuity between an electrode portion formed on the semiconductor device and the wiring substrate, and has a first bonding start temperature to start bonding to the wiring substrate, and the second bonding layer includes a second insulation layer having inorganic material as the main constituent, and an opening portion communicating with the through hole and configured to dispose the semiconductor device therein, and has a second bonding start temperature being a temperature to start bonding to the semiconductor device, the temperature being different from the first bonding start temperature.

### TECHNICAL FIELD

The present invention relates to a semiconductor module including a semiconductor device, a wiring substrate, and a heat sink.

### BACKGROUND ART

Conventionally, used is a semiconductor module with a multi-layer structure, including a semiconductor device having electrodes on both front and back surfaces, a first and a second wiring substrate connected to the surfaces of the semiconductor device, and a bonding layer that bonds between the first and second wiring substrates and the semiconductor device. Such a semiconductor module is manufactured by using, for example, the bonding layer formed by laminating a first bonding layer formed on the first wiring substrate side, and a second bonding layer formed on the second wiring substrate side and including an opening portion formed in a manner where the semiconductor device can be housed.

Specifically, the semiconductor module is manufactured through a first step of mounting the semiconductor device in the opening portion of the second bonding layer, and inspecting the bonding state of the first wiring substrate disposed on the first bonding layer, and the semiconductor device, and a second step of, after the inspection, disposing the second wiring substrate on a surface of the second bonding layer opposite to the surface where the first bonding layer is laminated, sandwiching the semiconductor device between the first and second wiring substrates, thermocompressively bonding the wiring substrates, the semiconductor device, and the bonding layer into one piece, and then sealing/bonding the semiconductor device and the wiring substrates.

### CITATION LIST

### Patent Literature

Patent Literature 1: JP-A-2007-287833

### DISCLOSURE OF THE INVENTION

### Problems to be Solved by the Invention

However, the above-mentioned technique has various problems in each step since the first and second bonding layers start softening at substantially the same timing in heating processes of the first and second steps if the first and second bonding layers comprise the same material. For example, in the first step, there arises problems such as complication of the manufacturing process due to the erosion of the second bonding layer to a pressurizing jig used to mount the semiconductor device, excessive deformation of the first bonding layer due to the resoftening of the first bonding layer that was already bonded to the first wiring substrate in the first step, and a reduction in the applied pressure to the second bonding layer. Moreover, the known technique needs to form a larger opening portion than the outside shape of the semiconductor device in order to smoothly fit the semiconductor device into the opening portion. In other words, in terms of the cross section in the lamination direction, the cross-sectional area of the opening portion is larger than that of the semiconductor device. Hence, after the semiconductor device is mounted, a gap may be created between the side surface of the semiconductor device and the side wall of the opening portion, which may lead to a reduction in the insulation performance between the semiconductor device and the wiring substrates. In addition, conventionally, the size reduction of the semiconductor module, and the facilitation and simplification of its manufacturing process are desired.

### Solutions to the Problems

The present invention has been made to solve at least a part of the above problems and can be realized as the following modes.

(1) According to one mode of the present invention, a semiconductor module is provided. The semiconductor module includes: a wiring substrate where a via and interconnecting pattern are formed; a semiconductor device disposed on a first surface side of the wiring substrate; and a bonding portion, disposed on the first surface of the wiring substrate, for bonding the semiconductor device and the wiring substrate, the bonding portion including a first bonding layer disposed on the wiring substrate side, and a second bonding layer disposed on the semiconductor device side, wherein the first bonding layer includes: a first insulation layer having inorganic material as a main constituent; at least one through hole formed in an area of the first insulation layer corresponding to the via; and a conductive bonding portion, disposed in the through hole, for establishing electrical continuity between an electrode portion formed on the semiconductor device and the wiring substrate, and has a first bonding start temperature being a temperature to start bonding to the wiring substrate, and the second bonding layer includes: a second insulation layer having inorganic material as a main constituent; and an opening portion communicating with the through hole and configured to dispose the semiconductor device therein, and has a second bonding start temperature being a temperature to start bonding to the semiconductor device, the temperature being different from the first bonding start temperature. According to the semiconductor module of the mode, the bonding layer for bonding the wiring substrate and the semiconductor device is formed of the first bonding layer having the first bonding start temperature, and the second bonding layer having the second bonding start temperature different from the first bonding start temperature. Therefore, during the thermocompression bonding at the time of bonding the wiring substrate and the semiconductor device, the first and the second bonding layer start being bonded to the wiring substrate, the semiconductor device, and other electronic components, respectively, at different timings. Hence, it is possible to prevent various problems arising when the first and the second bonding layer start being bonded at substantially the same timing, and improve manufacturing efficiency when manufacturing the semiconductor module with a circuit substrate.
(2) In the semiconductor module of the mode, the first bonding start temperature may be set to be lower than the second bonding start temperature. According to the semiconductor module of the mode, the first bonding start temperature is lower than the second bonding start temperature. Therefore, the deformation of the second bonding layer is suppressed in the heating/pressurizing process at the time of mounting the semiconductor at the first bonding start temperature. Hence, it is possible to suppress the erosion of the second bonding layer to a pressurizing jig used for the mounting of the semiconductor at the time of the mounting of the semiconductor. Thus, the complication of the manufacturing process is suppressed and the manufacturing efficiency can be improved.
(3) In the semiconductor module of the mode, the first bonding start temperature may be set to be higher than the second bonding start temperature. According to the semiconductor module of the mode, the first bonding start temperature is higher than the second bonding start temperature. Therefore, when the second bonding layer is bonded to another component at the second bonding temperature, it is possible to suppress the excessive deformation of the first bonding layer already bonded to the semiconductor device and the wiring substrate due to the reapplication of heat/pressure, and a reduction in the applied pressure to the second bonding layer. Hence, manufacturing efficiency can be improved.
(4) According to one mode of the present invention, a circuit substrate is provided. The circuit substrate includes: a wiring substrate where a via and a interconnecting pattern are formed; and a bonding portion, disposed on a first surface of the wiring substrate, for bonding a semiconductor device and the wiring substrate, the bonding portion including a first bonding layer disposed on the wiring substrate side, and a second bonding layer disposed on the semiconductor device side, wherein the first bonding layer includes: a first insulation layer having inorganic material as a main constituent; at least one through hole formed in an area of the first insulation layer corresponding to the via; and a conductive bonding portion, disposed in the through hole, for establishing electrical continuity between an electrode portion formed on the semiconductor device and the wiring substrate, and has a first bonding start temperature being a temperature to start bonding to the wiring substrate, and the second bonding layer includes: a second insulation layer having inorganic material as a main constituent; and an opening portion communicating with the through hole and configured to dispose the semiconductor device therein, and has a second bonding start temperature being a temperature to start bonding to the semiconductor device, the temperature being different from the first bonding start temperature. According to the circuit substrate of the mode, the bonding layer for bonding the wiring substrate and the semiconductor device includes the first bonding layer having the first bonding start temperature, and the second bonding layer having the second bonding start temperature different from the first bonding start temperature. Therefore, during the thermocompression bonding at the time of bonding the wiring substrate and the semiconductor device, the first and the second bonding layer start being bonded to the wiring substrate, the semiconductor device, and other electronic components, respectively, at different timings. Hence, it is possible to prevent various problems arising when the first and the second bonding layer start being bonded at substantially the same timing, and improve manufacturing efficiency when manufacturing a semiconductor module using the circuit substrate.
(5) In the circuit substrate of the mode, the first bonding start temperature may be set to be lower than the second bonding start temperature. According to the circuit substrate of the mode, the first bonding start temperature is lower than the second bonding start temperature. Therefore, the deformation of the second bonding layer is suppressed in the heating/pressurizing process at the time of mounting the semiconductor at the first bonding start temperature. Hence, it is possible to suppress the erosion of the second bonding layer to a pressurizing jig used for the mounting of the semiconductor at the time of the mounting of the semiconductor. Thus, the complication of the manufacturing process is suppressed, and manufacturing efficiency can be improved.
(6) In the circuit substrate of the mode, the first bonding start temperature may be set to be higher than the second bonding start temperature. According to the circuit substrate of the mode, the first bonding start temperature is higher than the second bonding start temperature. Therefore, when the second bonding layer is bonded to another component at the second bonding temperature, it is possible to suppress the excessive deformation of the first bonding layer already bonded to the semiconductor device and the wiring substrate due to the reapplication of heat/pressure, and a reduction in the applied pressure to the second bonding layer. Hence, the manufacturing efficiency when manufacturing the semiconductor module using the circuit substrate can be improved.
(7) In the circuit substrate of the mode, the depth of the opening portion may be set to be larger than a distance between a top side of the opening portion and an underside of the semiconductor device when the semiconductor device is disposed in the opening portion. According to the circuit substrate of the mode, the opening portion of the bonding layer is formed such that the depth of the opening portion is larger than the distance between the top side of the opening portion and the underside of the semiconductor device. Therefore, it is possible to produce a surplus member, in the bonding layer, corresponding to a difference between the depth of the opening portion and the distance between the top side of the opening portion and the underside of the semiconductor device. Hence, if a gap is created between the wiring substrate and the bonding layer or between a side wall of the opening portion of the bonding layer and a side surface of the semiconductor device, it is possible to cover (fill) the gap with the surplus member. Therefore, it is possible to promote the prevention of discharge on a creepage surface of the semiconductor device due to an improvement in insulating property between the semiconductor device and the wiring substrate, and the suppression of damage to the semiconductor device due to the existence of the gap. Moreover, also when a gap is created between the wiring substrate and the bonding layer due to the warpage of the wiring substrate occurring during manufacture, the gap can be covered (filled) with the surplus member. Therefore, the bond strength between the wiring substrate and the bonding layer can be improved.
(8) The circuit substrate of the mode may be set such that the through hole is formed to have a volume equal to or more than a summation of the volume of the conductive bonding portion and the volume of the electrode portion of the semiconductor device, and the depth of the opening portion is larger than the thickness of a casing of the semiconductor device. According to the circuit substrate of the mode, the through hole is formed to have a volume equal to or more than a summation of the volume of the conductive bonding portion and the volume of the electrode portion of the semiconductor device, and the opening portion is formed such that its depth is larger than the thickness of the semiconductor device. Therefore, upon the mounting of the semiconductor device in the opening portion, the entire electrode portion is housed in the through hole to ensure contact between a top surface of the casing of the semiconductor device and the top side of the opening portion. Hence, the insulating property between the top surface of the casing of the semiconductor device and the bonding layer can be secured, and as a consequence, discharge on the creepage surface of the semiconductor device can be prevented. Moreover, the gap formed between the side surface of the semiconductor device and the side wall of the opening portion can be filled with the surplus member of the bonding layer.
(9) The circuit substrate of the mode may be formed such that the volume of the surplus portion of the bonding layer corresponding to the difference between the depth of the opening portion and the distance between the top side of the opening portion and the underside of the semiconductor device is equal to or more than the volume of the gap formed between the semiconductor device and the opening portion. According to the circuit substrate of the mode, the bonding layer is formed such that the volume of the surplus portion is equal to or more than the volume of the gap formed between the semiconductor device and the opening portion. Therefore, the gap formed between the semiconductor device and the opening portion can be filled more securely.
(10) In the circuit substrate of the mode, the opening portion may be formed in a tapered shape. According to the circuit substrate of the mode, the opening portion is formed to have a tapered shape. Therefore, pressure is applied in the lamination direction upon the bonding of the bonding layer and the wiring substrate, and the filling efficiency of the gap can be improved and the occurrence of gas bubbles can be suppressed. Hence, the insulating property between the wiring substrate and the semiconductor device can be improved.
(11) In the circuit substrate of the mode, an inner wall of the opening portion may be formed in a flat shape in a lamination layer direction. According to the circuit substrate of the mode, the inner wall of the opening portion is formed in a flat shape in the lamination direction. Therefore, the opening portion can be manufactured by a simple method such as punching.

All of the plurality of components included in the above-mentioned modes of the present invention are not indispensable. However, part of the components of the plurality of components can be changed, deleted, replaced with other new components, and their limited contents can be partly deleted, as appropriate, in order to solve part or all of the above-mentioned problems or achieve part or all of the effects described in the description. Moreover, in order to solve part or all of the above-mentioned problems or achieve part or all of the effects described in the description, it is also possible that part or all of the technical features included in the above-mentioned one mode of the present invention is combined with part or all of the technical features included in the above-mentioned another mode of the present invention to make the combination an independent mode of the present invention.

### BRIEF DESCRIPTION OF THE DRAWINGS

FIG. 1 is an illustrative cross-sectional view of a configuration of a semiconductor module of an embodiment of the present invention.

FIG. 2 is an illustrative cross-sectional view of a schematic configuration of a bonding portion 20 in a first embodiment.

FIG. 3 is a flowchart illustrating a procedure of a method for manufacturing a semiconductor module in the first embodiment.

FIGS. 4A to 4C are explanatory diagrams illustrating the creation of a first bonding layer 130.

FIGS. 5A and 5B are explanatory diagrams illustrating the creation of a second bonding layer 140.

FIG. 6 is a flowchart illustrating a detailed procedure of an assembly process illustrated in FIG. 3.

FIG. 7 is an explanatory diagram illustrating the creation of a circuit substrate 70 in Step S405 of the first embodiment.

FIG. 8 is an explanatory diagram illustrating a bonding step in Step S415.

FIGS. 9A and 9B are explanatory diagrams illustrating a bonding state of an electrode portion 32 of a semiconductor device 30, and a conductive bonding portion 136 in Step S415.

FIG. 10 is an explanatory diagram illustrating the attachment of a heat dissipation substrate 80 and a heat sink 50 to a circuit substrate 70 in Step S440.

FIGS. 11A and 11B are partially enlarged sectional views illustrating a bonding state of a bonding portion 20 the semiconductor device 30, and the heat dissipation substrate 80 in Step S440.

FIG. 12 is an illustrative cross-sectional view of a schematic configuration of a semiconductor power module 1010 in a third embodiment.

FIG. 13 is an exploded sectional view of the semiconductor power module 1010 before bonding in the third embodiment.

FIG. 14 is a process drawing illustrating a method for manufacturing the semiconductor power module 1010 in the third embodiment.

FIGS. 15A to 15C are explanatory diagrams illustrating the creation of a first bonding layer 630.

FIGS. 16A and 16B are explanatory diagrams illustrating the creation of a second bonding layer 640.

FIG. 17 is an explanatory diagram illustrating temporary adhesion of a first wiring substrate 600 and the first bonding layer 630 in the third embodiment.

FIG. 18 is an explanatory diagram illustrating the formation of a bonding layer 620 in the third embodiment.

FIG. 19 is an explanatory diagram illustrating the mounting state of a semiconductor device 650 in the third embodiment.

FIG. 20 is an explanatory diagram illustrating temporary adhesion of a second wiring substrate 610 and the bonding layer 620 in the third embodiment.

FIGS. 21A and 21B are explanatory diagrams illustrating the filling of a gap 550 portion by a surplus portion 648 upon diffusion bonding.

FIGS. 22A and 22B are explanatory diagrams illustrating the filling of a gap 560 portion between a bonding layer 720 and the semiconductor device 650 in a fourth embodiment.

### DESCRIPTION OF EMBODIMENTS

### A. First Embodiment

### A1. Configuration of Semiconductor Module

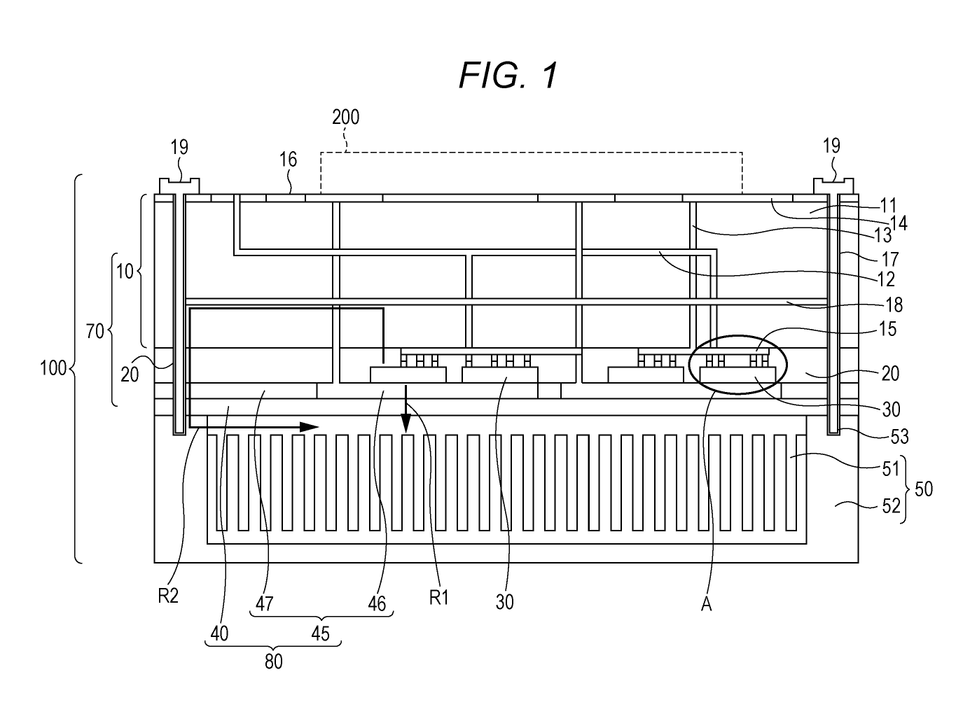

FIG. 1 is an illustrative cross-sectional view of a configuration of a semiconductor module of an embodiment of the present invention. A semiconductor module 100 is what is called a power module, and is used for applications such as power control in an automobile and the like. The semiconductor module 100 includes a wiring substrate 10, a plurality of semiconductor devices 30, a bonding portion 20, a heat dissipation substrate 80, a heat sink 50, and a plurality of screws 19. The semiconductor module 100 has a multi-layer structure where the components (the wiring substrate 10, the plurality of semiconductor devices 30, the bonding portion 20, the heat sink 50, and the heat dissipation substrate 80, excluding the screws 19) are laminated. Specifically, the heat dissipation substrate 80 is disposed on the heat sink 50. The semiconductor devices 30 and the bonding portion 20 are disposed on the heat dissipation substrate 80. The wiring substrate 10 is disposed on the bonding portion 20. The wiring substrate 10 and the heat sink 50 are fastened by the screws 19. A low heat generating component 200 can be laminated on the wiring substrate 10. The low heat generating component 200 is an electronic component that has a lower calorific value than that of the semiconductor device 30, and corresponds to, for example, a control semiconductor device, or a capacitor. The wiring substrate 10 and the bonding portion 20 constitute a circuit substrate 70. In the first embodiment, the wiring substrate 10 corresponds to a “wiring substrate” in the claims.

The wiring substrate 10 includes a ceramic layer 11, a control circuit wiring 12, a main power straight via 13, an upper surface wiring 14, a lower surface wiring 15, a first insulation bonding portion 16, a screw housing portion 17, and a heat dissipation layer 18.

The ceramic layer 11 comprises ceramic material or glass-ceramic material where glass component is blended. For example, aluminum oxide (Al₂O₃), aluminum nitride (AlN), and silicon nitride (Si₃N₄) can be adopted as the ceramic material. The control circuit wiring 12 is wiring formed in the ceramic layer 11, and is used for purposes such as the transmission of a control signal (a signal to drive the semiconductor device 30). The main power straight via 13 is a conductive member that penetrates the ceramic layer 11 in a thickness direction (lamination direction), and electrically connects the upper surface wiring 14 and the lower surface wiring 15. The lower surface wiring 15 is disposed on a surface in contact with the bonding portion 20 (hereinafter referred to as the “first surface”) among the surfaces of the ceramic layer 11. The upper surface wiring 14 is disposed on a surface to which the low heat generating component 200 can be bonded (hereinafter referred to as the “second surface”) among the surfaces of the ceramic layer 11. The first insulation bonding portion 16 comprises a glass composition having insulating inorganic material as the main constituent, and is disposed around the upper surface wiring 14 on the second surface.

As a base material of the control circuit wiring 12 and the main power straight via 13 that are formed in the above-mentioned ceramics, it is desired to adopt an arbitrary conductive material such as silver, copper, tungsten, and molybdenum. Furthermore, a conductive material that can be sintered concurrently with the ceramic layer 11 can be adopted. A similar material to that of the control circuit wiring 12 may be adopted for the surface wirings 14 and 15, or the multilayer wiring substrate including the ceramic layer 11, the control circuit wiring 12, and the main power straight via 13 is sintered concurrently, and then a conductive material such as silver, copper, nickel, and aluminum may be formed by another process such as plating or printing. FIG. 1 illustrates such that a level difference corresponding to the layer thickness of the lower surface wiring 15 is formed at a bonding interface between the wiring substrate 10 and the bonding portion 20. However, in reality, the lower surface wiring 15 is formed in a thin-film form, and such a level difference as illustrated is hardly been created at the bonding interface between the wiring substrate 10 and the bonding portion 20. Moreover, a level difference correction layer of the same type of material as the bonding portion 20, corresponding to the level difference, may be provided at the bonding interface between the wiring substrate 10 and the bonding portion 20. Hence, hereinafter, the description and drawings are illustrated while the description of the lower surface wiring 15 is omitted.

The screw housing portion 17 is a long hole that penetrates the first insulation bonding portion 16, the ceramic layer 11, the bonding portion 20, an electrode wiring layer 45, and an insulating substrate 40, and houses the screw 19. A housing surface of the screw housing portion 17 is covered with material having excellent thermal conductivity. As the material, for example, silver, copper, nickel, and aluminum can be adopted. As described below, the screw housing portion 17 forms a part of a heat dissipating path of the heat emitted from the semiconductor device 30. Thus, in the semiconductor module 100, the housing surface of the screw housing portion 17 is covered with material having excellent thermal conductivity to improve heat dissipation. A method for applying paste including a high thermal conductive material to the housing surface of the screw housing portion 17, or plating the housing surface of the screw housing portion 17 with a high thermal conductive material can be adopted as the covering method. A thread ridge can also be formed in at least part of the screw housing portion 17.

The heat dissipation layer 18 is disposed parallel with the ceramic layer 11 in the ceramic layer 11. The heat dissipation layer 18 can be formed of an arbitrary material having excellent thermal conductivity, and an arbitrary conductive material that can be sintered concurrently with the ceramic layer, such as silver, copper, tungsten, and molybdenum, can be adopted as in, for example, the base material of the control circuit wiring 12 and the main power straight via 13. The heat dissipation layer 18 is provided with a plurality of unillustrated through holes, and is not electrically connected to the semiconductor device 30 since the control circuit wiring 12 and the main power straight via 13 are disposed in the through holes. The heat dissipation layer has a configuration that is not involved in electrical wiring. Moreover, a part of the edge of the heat dissipation layer 18 is in contact with the housing surface of the screw housing portion 17 and the screw 19, and it is possible to form a heat dissipating path that is continuous from the inside of the wiring substrate 10.

The semiconductor device 30 is a power semiconductor device (power device), and can adopt a power MOSFET (Metal-Oxide-Semiconductor Field-Effect Transistor), a diode (schottky barrier diode or the like), and the like. The semiconductor device 30 includes an electrode portion 32 and an electrode wiring layer 39 for electrically connecting the lower surface wiring 15 and an electrode wiring to be described below. The electrode portion 32 includes an electrode pad and a bump (protruding metal terminal). The electrode portion 32 corresponds to an “electrode portion” in the claims.

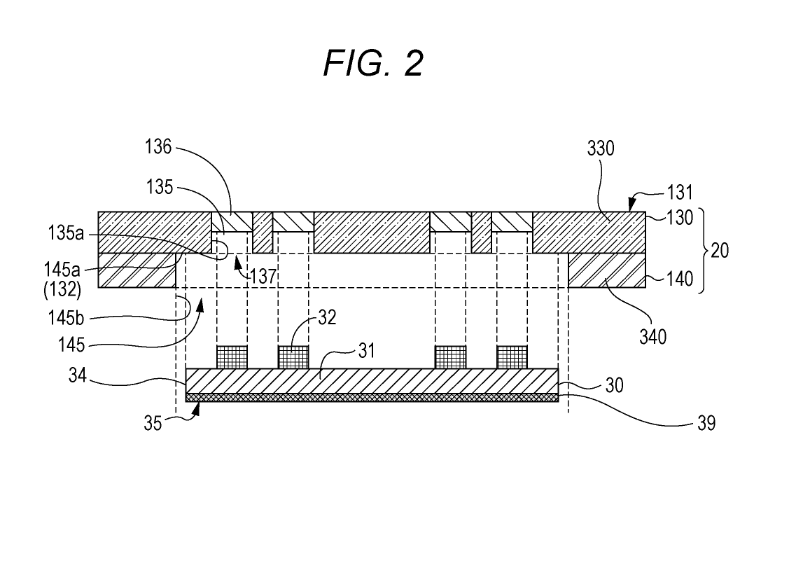

The bonging portion 20 is a thin insulating glass sheet that insulates the semiconductor device 30 from the wiring substrate 10 and the heat dissipation substrate 80. The bonding portion 20 has insulating inorganic material as the main constituent, and comprises powered glass that softens in the heating process upon the mounting of the semiconductor device. The powdered glass comprises, for example, silicon oxide, zinc oxide, boron oxide, and bismuth oxide. The detailed configuration of the bonding portion 20 will be described with reference to FIG. 2.

FIG. 2 is an illustrative cross-sectional view of a schematic configuration of the bonding portion 20 in the first embodiment. FIG. 2 illustrates an area corresponding to the portion of a circle A in FIG. 1, and also bears the semiconductor device 30 in order to describe the positional relationship between the semiconductor device and the bonding portion 20 upon the mounting of the semiconductor device. The bonding portion 20 includes a first bonding layer 130 and a second bonding layer 140.

The first bonding layer 130 includes an insulating glass sheet 330 comprising powdered glass including inorganic material, for example, Bi₂O₃ and B₂O₃, and at least one through hole 135 formed at a position P of the glass sheet 330 corresponding to the lower surface wiring 15, and a conductive bonding portion 136 disposed in the through hole 135, and insulates between the wiring substrate 10 and the semiconductor device 30. In other words, the through hole 135 of the first bonding layer 130 is formed at a top side 145a of an opening portion 145 of the second bonding layer 140 to be described below. The conductive bonding portion 136 is disposed in the through hole 135. Thus, a recess 137 is formed by the conductive bonding portion 136 and a side wall 135a of the through hole 135. If a level difference correction portion corresponding to the level difference is disposed at the bonding interface between the wiring substrate 10 and the bonding portion 20, the level difference correction portion may be constructed as a part of the first bonding layer 130. The glass sheet 330 corresponds to a “first insulation layer” in the claims.

The first bonding layer 130 has a first bonding start temperature being a temperature at which the first bonding layer 130, the wiring substrate 10, and the semiconductor device 30 start to be bonded. The first bonding start temperature is equal to or higher than a sintering start temperature at which at least a portion of the material constituting the first bonding layer 130 starts a sintering reaction. The sintering start temperature is a temperature at which the sintering reaction starts, due to formation of a liquid phase by at least a portion of the components constituting the first bonding layer 130 or due to a reaction on an adhesive interface in a solid phase. Even if the first bonding layer 130 is not melting, the generation of the liquid phase of a limited part of the constituents advances sintering and adhesion to start bonding to another member. The temperature to start a sintering reaction of the powdered glass including Bi₂O₃ and B₂O₃ constituting the first bonding layer 130 is 357° C. Hence, it is sufficient if the first bonding start temperature is 357° C. or higher, and the first bonding start temperature may be set to, for example, a temperature equal to or higher than the melting point or softening point. In the first embodiment, the first bonding start temperature is 450° C. that is slightly higher than the softening point (435° C.) of the powdered glass (Bi₂O₃ and B₂O₃) constituting the first bonding layer 130.

The conductive bonding portion 136 has conductive metal as the main constituent. For example, copper, silver, tin, and aluminum may be used as the conductive metal. The conductive bonding portion 136 establishes electrical continuity between the electrode portion 32 of the semiconductor device 30 and the wiring substrate 10 if the semiconductor device 30 is disposed in the opening portion 145.

The second bonding layer 140 includes an insulating glass sheet 340 comprising powdered glass including inorganic materials, for example, Na₂O₃, B₂O₃, and SiO₂, and the opening portion 145 for disposing the semiconductor device 30 therein, the opening portion 145 being formed in the glass sheet 340 and communicating with the through hole 135, and insulates the semiconductor device 30 from the heat dissipation substrate 80. Moreover, the second bonding layer 140 is formed on a second surface 132 side different from a first surface 131 on which the wiring substrate 10 is laminated. When the semiconductor device 30 is disposed in the opening portion 145, the electrode portion 32 of the semiconductor device 30 is housed in the through hole 135, and electrical continuity is established between the electrode portion 32 and the wiring substrate 10. The glass sheet 340 corresponds to a “second insulation layer” in the claims.

The second bonding layer 140 has a second bonding start temperature being a temperature at which the second bonding layer 140, the heat dissipation substrate 80, and the semiconductor device 30 start to be bonded, the temperature being higher than the first bonding start temperature. The second bonding start temperature is a temperature equal to or higher than a sintering start temperature at which at least part of the materials included in the second bonding layer 140 starts a sintering reaction. The temperature at which at least part of the materials included in the second bonding layer 140 starts a sintering reaction is a temperature to start a sintering reaction by the formation of a liquid phase by at least part of the constituents included in the second bonding layer 140, or a reaction in a solid phase at the bonding interface. Even if the second bonding layer 140 is not melting, the generation of the liquid phase of a limited part of the constituents advances sintering and adhesion to start bonding to another member. The temperature to start a sintering reaction of the powdered glass including Na₂O₃, B₂O₃, and SiO₂ constituting the second bonding layer 140 is 495° C. that is higher than 357° C. being the first bonding start temperature. Hence, it is sufficient if the second bonding start temperature is 495° C. or higher, and the second bonding start temperature may be set to, for example, a temperature equal to or higher than the melting point or softening point. In the first embodiment, the second bonding start temperature is 600° C. that is slightly higher than the softening point (585° C.) of the powdered glass (Na₂O₃, B₂O₃, and SiO₂) constituting the second bonding layer 140.

Moreover, as illustrated in FIG. 2, the opening portion 145 is formed larger than the outside shape of a casing 31 of the semiconductor device 30 to create a gap of approximately several μm to several mm between a side surface 34 of the semiconductor device 30 and a side wall 145b of the opening portion 145. Consequently, it is possible to smoothly fit the semiconductor device 30 into the opening portion 145.

Returning to FIG. 1, the description is continued. The heat dissipation substrate 80 includes the insulating substrate 40, and the electrode wiring layer 45 disposed on the insulating substrate 40, and is disposed such that the electrode wiring layer 45 is opposed to the semiconductor device 30.

The electrode wiring layer 45 includes an electrode wiring 46 and a third insulation bonding portion 47. The electrode wiring 46 is connected to the semiconductor device 30 and the main power straight via 13. The third insulation bonding portion 47 is disposed around the electrode wiring 46. The third insulation bonding portion 47 comprises insulating material, and secures the insulating property between the electrode wiring 46 and the wiring substrate 10. In the embodiment, the third insulation bonding portion 47 comprises the same base material as the second bonding layer 140. Moreover, if the third insulation bonding portion 47 has different base material from the second bonding layer 140, a level difference correction layer of the same type of material as the bonding portion 20, corresponding to the level difference of the bonding part, may be provided at the bonding interface between the third insulation bonding portion 47 and the bonding portion 20. The level difference correction portion may be constructed as a part of the second bonding layer 140.

The insulating substrate 40 secures the insulating property between the semiconductor device 30 and the heat sink 50 and the insulating property between the electrode wiring 46 and the heat sink 50. In the embodiment, the above-mentioned ceramic material is adopted as the base material of the insulating substrate 40. The insulating substrate 40 and the heat sink 50 are not adhered to but are in intimate contact with each other. The following is the reason of not being adhered but being in intimate contact in this manner.

The base material (ceramics) of the insulating substrate 40 and the base material (metal) of the heat sink 50 are different in thermal expansion coefficient. Thus, if the insulating substrate 40 and the heat sink 50 are adhered, when the semiconductor module 100 becomes a high temperature due to the heat of the semiconductor device 30, a large stress can occur between the insulating substrate 40 and the heat sink 50, or at the bonding interface between the semiconductor device 30 and the electrode wiring layer 45 (the electrode wiring 46) due to the deformation of the insulating substrate 40 and the electrode wiring layer 45 (especially, the electrode wiring layer 46 disposed in contact with the semiconductor device 30) caused in the wake of the deformation of the heat sink 50.

In contrast, if the insulating substrate 40 and the heat sink 50 are disposed in contact with each other without being adhered, the insulating substrate 40 or the heat sink 50 can slide (be displaced) at the interface between the insulating substrate 40 and the heat sink 50. Thus, it is possible to suppress the occurrence of stress that can be caused at the bonding interface between the insulating substrate 40 and the heat sink 50, and the deformation of the insulating substrate 40 and the electrode wiring layer 45 (the electrode wiring 46) and the occurrence of stress that can be caused at the bonding interface between the insulating substrate 40 and the electrode wiring 45 (the electrode wiring 46) due to the deformation, and to reduce the caused stress. Hence, it is possible to prevent damage to the insulating substrate 40 and the heat sink 50, and the deformation of the insulating substrate 40 and damage to the insulating substrate 40 and the semiconductor device 30 due to the deformation.

In the embodiment, “bonding” means that the semiconductor device 30 and the surface wiring 15 are integrally adhered by thermal fusion or the like via a conductive bonding material such as a bump while, as described above, “intimate contact” means that the insulating substrate 40 and the heat sink 50 are disposed in contact with each other while the sliding (displacement) of the insulating substrate 40 and the heat sink 50 at the interface is allowed.

The heat sink 50 is disposed on a surface of the heat dissipation substrate 80, opposite to the surface where the bonding portion 20 is disposed. It is thermally connected to the semiconductor device 30, and absorbs and releases the heat of the semiconductor device 30. The heat sink 50 has a configuration where a fin 51 is formed in a housing 52. In the embodiment, a metal having excellent thermal conductivity (for example, copper, aluminum, and molybdenum) is adopted as the base material of the housing 52 and the fin 51. The housing 52 includes a screw hole 53 where a ridge is formed, and engages with the screw 19 in the screw hole 53. The housing 52 is provided with an unillustrated opening, and uses the opening to exchange the coolant heated by the heat dissipated from the fin 51 and the coolant outside the housing 52.

The screw 19 is housed in the screw housing portion 17 and the screw hole 53, and penetrates the wiring substrate 10, the bonding portion 20, and the heat dissipation substrate 80 in the direction to laminate these components (hereinafter simply referred to as the “lamination direction”) to fasten the wiring substrate 10 and the heat sink 50 with a predetermined fastening force. A head of the screw 19 is in contact with the surface of the wiring substrate 10, to which the low heat generating component 200 can be bonded. The reason why the wiring substrate 10 and the heat sink 50 are fastened by the predetermined fastening force using the screw 19 in this manner is that the layers (components) are brought into intimate contact with each other. Thus, electrical conductivity and thermal conductivity are improved and, even if stress occurs between the insulating substrate 40 and the heat sink 50, the deformation of the layers and interfacial delamination can be prevented.

Moreover, the screw 19 comprises a base material having excellent thermal conductivity. Copper, aluminum, molybdenum, and the like can be adopted as such a base material. Moreover, for example, a screw that has stainless as the base material and is plated with copper, aluminum, and the like can be adopted as the screw 19. As described below, the screw 19 forms a part of a heat dissipating path of the heat emitted from the semiconductor device 30 similarly to the above-mentioned housing surface of the screw housing portion 17. In the semiconductor module 100, the screw 19 comprises a base material having excellent thermal conductivity to improve heat dissipation.

In FIG. 1, the heat dissipating path of the heat emitted from the semiconductor device 30 is illustrated by the bold solid-line arrow. As illustrated in FIG. 1, the heat dissipating path in the semiconductor module 100 includes two paths (a path R1 and a path R2) illustrated in FIG. 1. The path R1 is a path to the heat sink 50 through the electrode wiring layer 45 (or the electrode wiring 46) and the insulating substrate 40. The path R2 is a path that reaches the heat dissipation layer 18 through the bonding portion 20 and the ceramic layer 11, reaches the housing surface of the screw housing portion 17 and the screw 19 along the heat dissipation layer 18, and reaches the heat sink 50 through the screw housing portion 17, the screw hole 53, and the screw 19. In FIG. 1, only the heat dissipating path for the semiconductor device 30 on the left end is illustrated, but similar two heat dissipating paths exist for other semiconductor devices 30.

### A2. Method for Manufacturing Semiconductor Module 100:

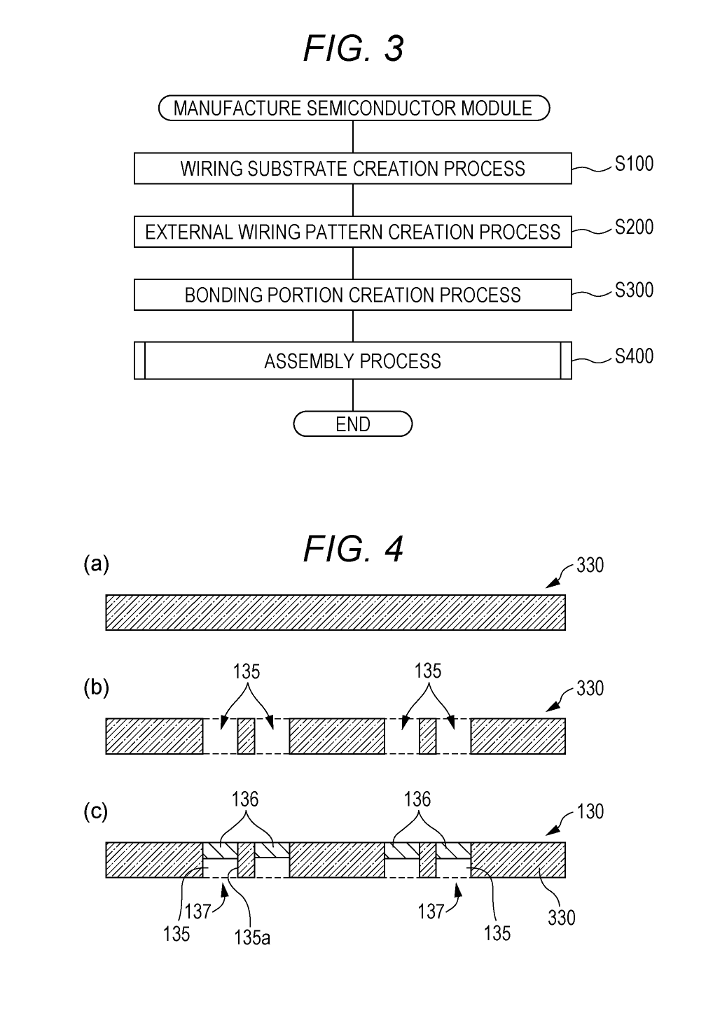

FIG. 3 is a flowchart illustrating a procedure of a method for manufacturing the semiconductor module in the first embodiment. Firstly, a process of creating the wiring substrate 10 (Step S100) is executed. The process includes the formation of the ceramic layer 11 comprising ceramic material constituting the wiring substrate 10, and the wiring (the control circuit wiring 12, the main power straight via 13, and the heat dissipation layer 18) in the ceramic layer 11.

A process of creating an external interconnecting pattern is executed after Step S100 (Step S200). In the process, the upper surface wiring 14 and the lower surface wiring 15 are formed on the surface of the wiring substrate 10 created in Step S100.

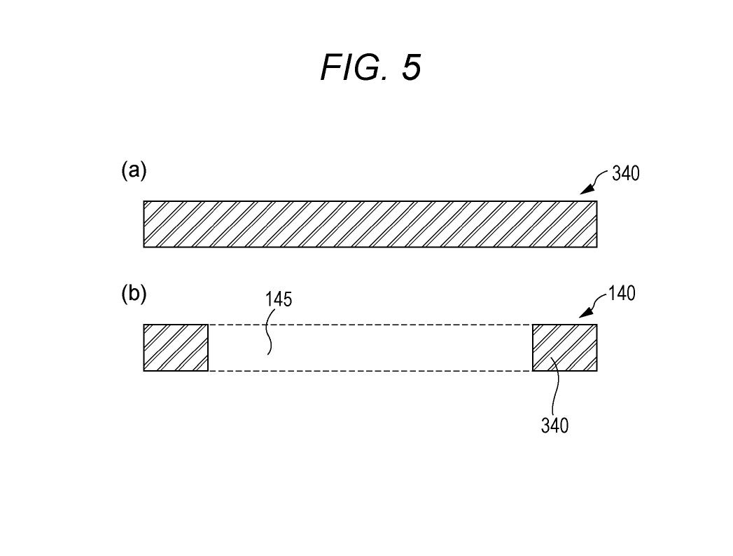

A process of creating the bonding portion 20 is executed after Step S200 (Step S300). In the process, the first bonding layer 130 and the second bonding layer 140, which constitute the bonding portion 20, are formed. FIGS. 4A to 4C are explanatory diagrams illustrating the creation of the first bonding layer 130. FIGS. 5A and 5B are explanatory diagrams illustrating the creation of the second bonding layer 140.

Firstly, the glass sheet 330 (FIG. 4A) included in the first bonding layer 130 and the glass sheet 340 (FIG. 5A) included in the second bonding layer 140 are created. Specifically, the slurry formed from powdered glass that softens by the application of heat in a diffusion bonding process, which is described below, and an organic binding agent having a thermal decomposition property with a solvent such as an organic solvent or water is molded in a sheet shape by sheet casting by a doctor blade method, or a method such as extrusion molding. The slurry is then dried to create the glass sheets 330 and 340. Powdered glass comprising silicon oxide, zinc oxide, boron oxide, lead oxide, and bismuth oxide can be used as the powdered glass. Moreover, ceramic powder material such as alumina may be blended as a filler in the glass sheets 330 and 340.

As illustrated in FIG. 4B, machining such as laser or microcomputer punching is performed at a position corresponding to the lower surface wiring 15 of the wiring substrate 10 on the created glass sheet 330 included in the first bonding layer 130. Thus, the through hole 135 is formed.

Next, as illustrated in FIG. 4C, the conductive bonding portion 136 is formed in the through hole 135. Specifically, paste included in the conductive bonding portion 136 is partially filled in the through hole 135 by screen printing. The paste has metal as the main constituent, and is formed by blending a metal species that melts by diffusion bonding, which is described below, such as aluminum metal, silver oxide, copper, nano metal, and solder alloy, and an organic binding agent having a thermal decomposition property with a solvent such as an organic solvent or water. The organic adhesive is decomposed and removed in a thermal process. The filling of the paste is not limited to screen printing. However, for example, a method such as ejection by a dispenser may be used. With the formation of the conductive bonding portion 136 in the through hole 135, the recess 137 is formed. In this manner, the first bonding layer 130 is formed.

Moreover, as illustrated in FIG. 5B, machining such as laser or microcomputer punching is performed at a position where the semiconductor device 30 is mounted on the glass sheet 340 included in the second bonding layer 140. Thus, the opening portion 145 is formed. At this point, the opening portion 145 is formed larger than the outside shape of the casing 31 of the semiconductor device 30 to create a gap of approximately several μm between the side surface 34 of the semiconductor device 30 and the side wall 145b of the opening portion 145. In this manner, the second bonding layer 140 is formed.

An assembly process is executed after Step S300 (Step S400). With the process, the wiring substrate 10 and other components (the electrode wiring layer 45, the insulating substrate 40, and the heat sink 50) are assembled.

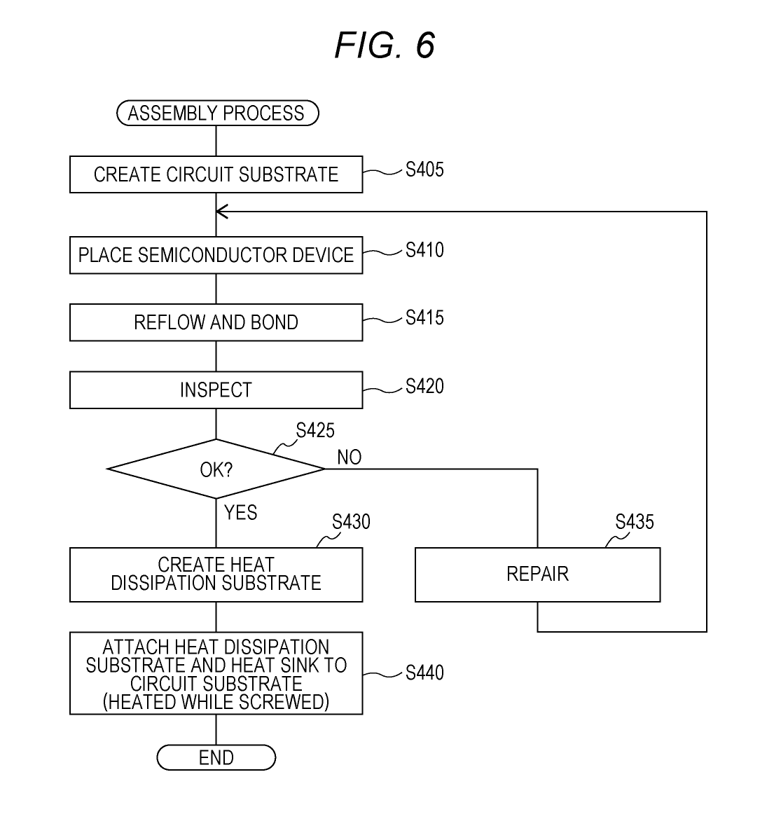

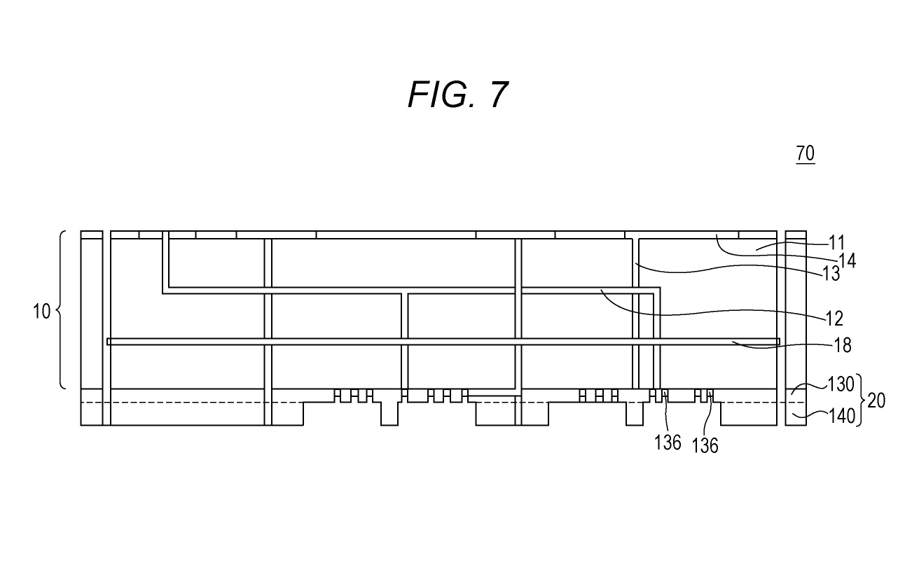

FIG. 6 is a flowchart illustrating a detailed procedure of the assembly process illustrated in FIG. 3. Firstly, the circuit substrate 70 is created (Step S405). The creation of the circuit substrate 70 will be described with reference to FIG. 7.

FIG. 7 is an explanatory diagram illustrating the creation of the circuit substrate 70 in Step S405 of the first embodiment. Specifically, the glass sheet 330 included in the first bonding layer 130, and the wiring substrate 10 are temporarily adhered by the adhesive strength of the organic binding agent included in the glass sheet 330.

Next, the second bonding layer 140 (the glass sheet 340) is positioned and laminated on the surface of the glass sheet 330 opposite to the surface on which the wiring substrate 10 is disposed. The glass sheet 330 and the second bonding layer 140 are temporarily adhered by the adhesive strength of the organic binding agent included in the glass sheet 330 and the second bonding layer 140. The conductive bonding portion 136 is filled in the through hole 135 of the glass sheet 330 to form the first bonding layer 130. With the formation of the bonding portion 20, the circuit substrate 70 including the wiring substrate 10 and the bonding portion 20 is created. The positioning of the glass sheet 330 and the second bonding layer 140 includes positioning to match the through hole 135 and the opening portion 145 with the mounting of the semiconductor device 30, in other words, to cause the through hole 135 and the opening portion 145 to communicate with each other, and house the electrode portion 32 in the recess 137 upon the placement of the semiconductor device 30 in the opening portion 145.

Next, the semiconductor device 30 having electrodes on both front and back surfaces is placed in the opening portion 145 (Step S410). The heating and pressurizing process is performed on the wiring substrate 10, the semiconductor device 30, and the bonding portion 20 to bond (reflow) the electrode portion 32 of the semiconductor device 30 and the conductive bonding portion 136, and to bond the wiring substrate 10, the bonding portion 20, and the semiconductor device 30 by diffusion bonding (Step S415).

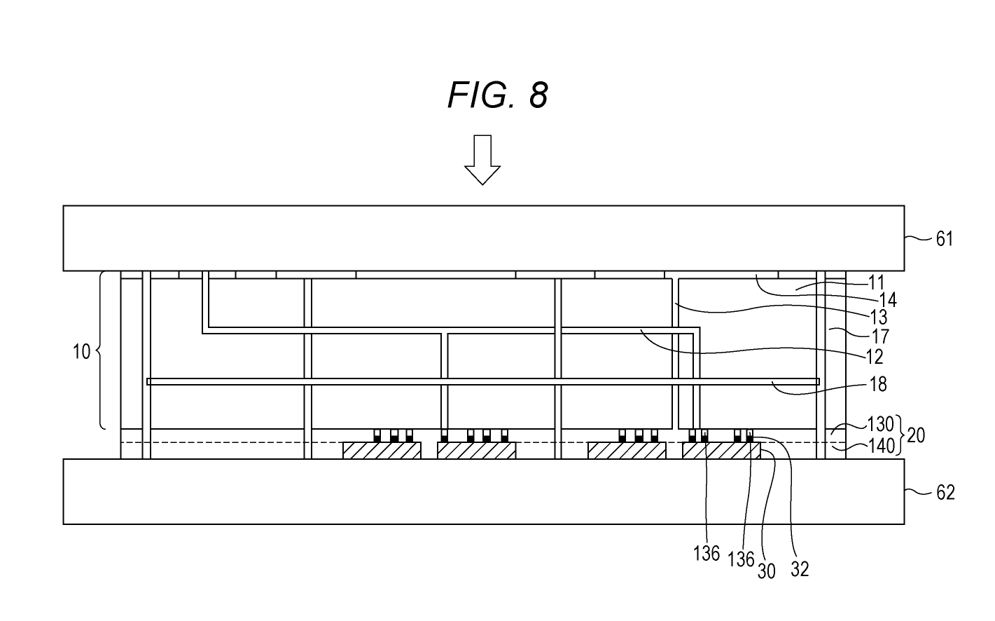

FIG. 8 is an explanatory diagram illustrating the bonding step in Step S415. As illustrated in FIG. 8, the wiring substrate 10, the bonding portion 20, and the semiconductor device 30 are held by a pressurizing jig including an upper jig 60 and a lower jig 61 in a state where the semiconductor device 30 is disposed in the opening portion 145, and are heated at the first bonding start temperature as well as being pressurized in the lamination direction. With the application of heat and pressure at the first bonding start temperature, the semiconductor device 30 and the first bonding layer 130 of the bonding portion 20, and the wiring substrate 10 and the first bonding layer 130 of the bonding portion 20 are bonded by diffusion bonding. In the first embodiment, the first bonding start temperature is, as already described, 450° C. The second bonding layer 140 comprises a material having the second bonding start temperature higher than the first bonding start temperature. Thus, the second bonding layer 140 does not melt and soften in the heating process in the bonding step. Hence, the erosion of the second bonding layer 140 to the lower jig 61 is suppressed.

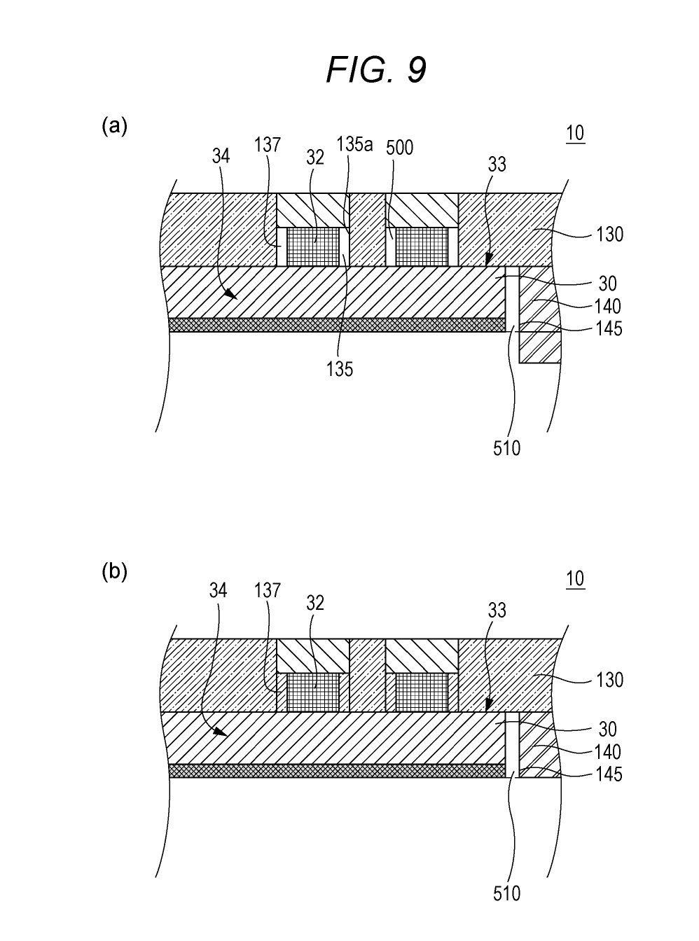

FIGS. 9A and 9B are explanatory diagrams illustrating a bonding state of the electrode portion 32 of the semiconductor device 30, and the conductive bonding portion 136 in Step S415. FIG. 9A illustrates the enlarged mounting location of the semiconductor device 30 before the thermocompression bonding. FIG. 9B illustrates the enlarged mounting location of the semiconductor device 30 after the thermocompression bonding.

As illustrated in FIG. 9A, the diameter of the electrode portion 32 of the semiconductor device 30 in the horizontal direction (the vertical direction with respect to the lamination direction) is formed smaller than the diameter of the recess 137 in the horizontal direction. Therefore, a gap 500 is formed between the electrode portion 32 and the side wall 135a of the recess 137 in a state where the semiconductor device 30 is housed in the opening portion 145, and the electrode portion 32 is housed in the recess 137.

As illustrated in FIG. 9B, when the wiring substrate 10, the bonding portion 20, and the semiconductor device 30 are heated and pressed in the lamination direction in the bonding step of Step S415, the first bonding layer 130 is pressed against the wiring substrate 10. At this point, the first bonding layer 130 is heated at the first bonding start temperature and then softens and falls in a state of being rich in fluidity. The gap 500 between the side wall 135a of the recess 137 and the electrode portion 32 of the semiconductor device 30 is filled with the first bonding layer 130.

When the placement (Step S410) and bonding (Step S415) of the semiconductor device 30 are completed, the bonding state of the semiconductor device 30 is inspected (Step S420), and whether or not the bonding is normal is determined (Step S425). If the bonding of the semiconductor device 30 is abnormal (Step S425: No), repair such as the removal and rebonding of the semiconductor device 30 is executed (Step S435), and the processing returns to Step S410.

If it is determined that the bonding of the semiconductor device 30 is normal in the above-mentioned Step S425 (Step S425: Yes), the heat dissipation substrate 80 is created (Step S430).

The following describes the creation of the heat dissipation substrate 80 specifically. Firstly, a thin ceramic plate member forming the insulating substrate 40 is created. The thin ceramic plate member is provided with a hole forming a screw housing portion 17. Next, a pattern for the electrode wiring 46 is created on the thin ceramic plate member. A glass sheet in which a via has been formed at a position where the electrode wiring 46 is disposed is created and attached to the thin ceramic plate member. The hole forming the screw housing portion 17 is provided in the glass sheet. In this manner, the heat dissipation substrate 80 where the electrode wiring layer 45 has been formed on the insulating substrate 40 is created.

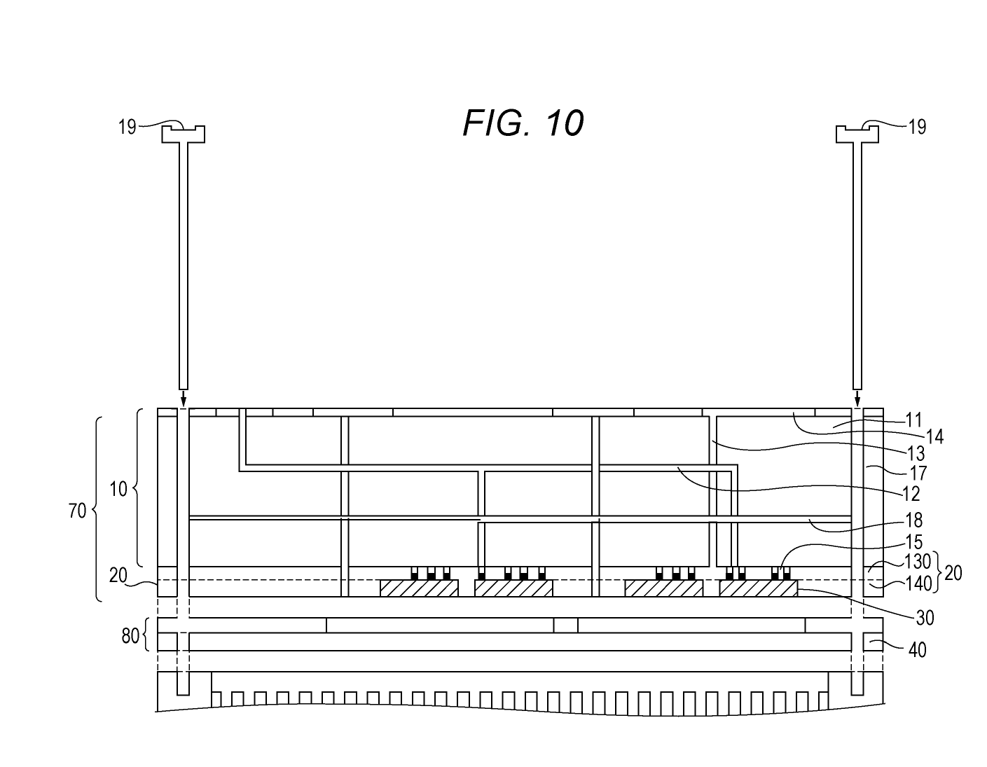

When the heat dissipation substrate 80 is created, the heat dissipation substrate 80 and the heat sink 50 are attached to the circuit substrate 70 where the semiconductor device 30 is mounted (Step S440). FIG. 10 is an explanatory diagram illustrating the attachment of the heat dissipation substrate 80 and the heat sink 50 to the circuit substrate 70 in Step S440. Firstly, the circuit substrate 70 is placed on the heat dissipation substrate 80, and the heat dissipation substrate 80 where the circuit substrate 70 has been placed is further placed on the heat sink 50 without being adhered. The screw 19 is housed in the screw housing portion 17 and the screw hole 53, and heated at the second bonding start temperature while being engaged in the screw hole 53, and fastening the wiring substrate 10 and the heat sink 50 with the predetermined fastening force.

The second bonding start temperature is, as already described, 600° C. The applied pressure is performed by the fastening of the screw 19 on the second bonding layer 140 of the bonding portion 20 and the heat dissipation substrate 80, and the second bonding layer 140 of the bonding portion 20 and the heat dissipation substrate 80 are heated at the second bonding start temperature and then melt and soften to cause atomic diffusion between the second bonding layer 140 and the heat dissipation substrate 80 and be bonded. Similarly, the second bonding layer 140 of the bonding portion 20 and the casing 31 of the semiconductor device 30 are heated at the second bonding start temperature and then melt and soften to cause atomic diffusion between the second bonding layer 140 and the casing 31 and be bonded.

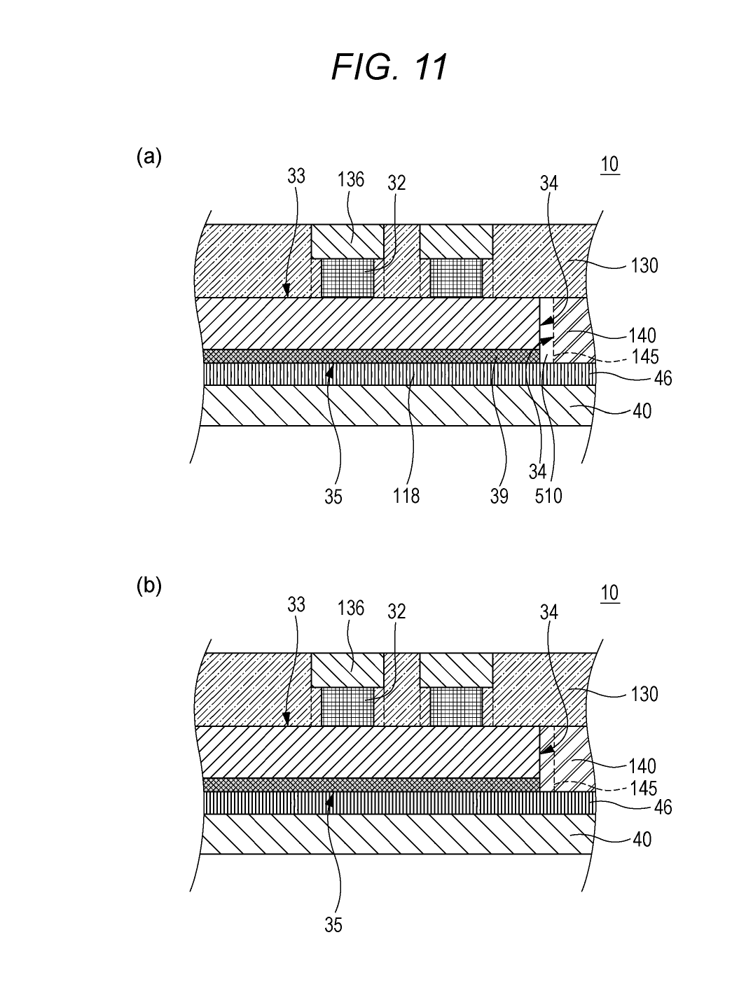

FIGS. 11A and 11B are partially enlarged sectional views illustrating a bonding state of the bonding portion 20, the semiconductor device 30, and the heat dissipation substrate 80 in Step S440. FIG. 11A illustrates the enlarged mounting location of the semiconductor device 30 before the thermocompression bonding. FIG. 11B illustrates the enlarged mounting location of the semiconductor device 30 after the thermocompression bonding.

As illustrated in FIG. 11A, the opening portion 145 is formed larger than the outside shape of the casing 31 of the semiconductor device 30. Thus, a gap 510 is formed between the side wall 145b of the opening portion 145 and the side surface 34 of the semiconductor device 30 in a state where the semiconductor device 30 is housed in the opening portion 145.

As illustrated in FIG. 11B, the bonding portion 20, the semiconductor device 30, and the heat dissipation substrate 80 are heated in diffusion bonding, and pressed in the lamination direction by the fastening of the screw 19. Accordingly, the heat dissipation substrate 80 is pressed against the semiconductor device 30 and the second bonding layer 140. At this point, the second bonding layer 140 is heated at the second bonding start temperature and then softens and falls in a state of being rich in fluidity. The gap 510 between the side wall 145b of the opening portion 145 and the semiconductor device 30 is filled with the second bonding layer 140. Consequently, the outer surface if the semiconductor device 30 is covered with the insulative second bonding layer 140. Thus, the insulating property between the electrode portion 32 of the semiconductor device 30 and the heat dissipation substrate 80 is improved to prevent discharge on the creepage surface of the semiconductor device 30.

With the filling of the gap 510, the thickness of the second bonding layer 140 becomes slightly thinner than the thickness before bonding. With the thinning of the second bonding layer 140, the electrode wiring layer 45 of the heat dissipation substrate 80, which is melting, spreads in the horizontal direction, and its thickness becomes slightly thinner. The electrode wiring layer 45 flows in this manner and then it can bring the bonding interfaces of the heat dissipation substrate 80, the second bonding layer 140, and the semiconductor device 30 to a substantially flat state where a gap and a bubble do not exist, and secure bond strength.

The following is the reason why the heat dissipation substrate 80 is placed on the heat sink 50 without being adhered. The deformation amounts (the deformation amounts with a change in temperature) of the heat sink 50 and the heat dissipation substrate 80 (the insulating substrate 40) are different due to a difference in thermal expansion coefficient between the heat sink 50 and the heat dissipation substrate 80 (the insulating substrate 40). Thus, stress can occur due to the difference in the deformation amount. However, the heat dissipation substrate 80 is placed on the heat sink 50 without being adhered. Thus, the heat sink 50 and the heat dissipation substrate 80 (the insulating substrate 40) can be disposed in contact with each other without being adhered to each other. Therefore, it is possible to suppress the occurrence of stress due to the difference in deformation amount between the heat sink 50 and the insulating substrate 40, and to reduce the stress. Hence, it is possible to suppress the occurrence of a large stress at the bonding interface between the semiconductor device 30 and the electrode wiring layer 45 (the electrode wiring 46). Thus, the connection area can be prevented from damaging.

When the above steps are executed, the semiconductor module 100 is finished. The low heat generating component 200 can be subsequently bonded to the semiconductor module 100. Specifically, for example, if the low heat generating component 200 is a semiconductor device including a bump, the semiconductor device 30 is placed such that the bump and the upper surface wiring 14 comes into contact with each other, and reflow is performed. Thus, the bump and the upper surface wiring 14 can be bonded.

According to the semiconductor module 100 of the first embodiment, which has been described above, the first bonding layer 130 and the second bonding layer 140 start being bonded to the wiring substrate 10, the heat dissipation substrate 80, the semiconductor device 30, and other electronic components, respectively, at different timings during the thermocompression bonding at the time of bonding the wiring substrate 10, the heat dissipation substrate 80, and the semiconductor device 30. Hence, it is possible to prevent various problems arising when the first bonding layer 130 and the second bonding layer 140 start being bonded at substantially the same timing, and improve manufacturing efficiency when manufacturing a semiconductor module on which a semiconductor device including interconnecting patterns on both front and back surfaces is mounted. In the first embodiment, the first bonding start temperature is lower than the second bonding start temperature. Thus, the deformation of the second bonding layer 140 is suppressed in the heating/pressurizing process at the time of the mounting the semiconductor device 30 at the first bonding start temperature. Hence, in the manufacturing process of the semiconductor module, it is possible to suppress the erosion of the second bonding layer 140 to the lower jig 61 of the pressurizing jig used for the mounting of the semiconductor device 30, suppress the complication of the manufacturing process, and improve manufacturing efficiency.

Moreover, according to the method for manufacturing the semiconductor module 100 of the first embodiment that has been described above, the first bonding layer 130 softens by the thermocompression bonding at the first bonding start temperature, and deforms to fill the gap between the through hole and the electrode portion. Therefore, it is possible to promote the prevention of damage to the semiconductor device and an improvement in the insulating property between the first wiring substrate and the second wiring substrate.

Moreover, according to the method for manufacturing the semiconductor module 100 of the first embodiment that has been described above, the second bonding layer softens by the thermocompression bonding at the second bonding start temperature, and deforms to fill the gap between the opening portion and the semiconductor device. Therefore, damage to the semiconductor device is prevented, and the insulating property between the wiring substrate 10, the heat dissipation substrate 80, and the semiconductor device 30 is improved, more specifically, the insulating property between the electrode portion 32 of the semiconductor device 30 and the electrode wiring 46 of the heat dissipation substrate 80 is improved. Thus, it is possible to promote the prevention of discharge on the creepage surface of the semiconductor device 30. Moreover, it is possible to promote the prevention of damage to the semiconductor device 30 due to the existence of the gap around the semiconductor device.

### B. Second Embodiment

In a second embodiment, materials included in the first bonding layer 130 and the second bonding layer 140 are determined such that the first bonding start temperature of the first bonding layer 130 is set to be higher than the second bonding start temperature of the second bonding layer 140. Specifically, the first bonding layer 130 comprises powdered glass including Na₂O₃, B₂O₃, and SiO₂. The softening point of the powdered glass including Na₂O₃, B₂O₃, and SiO₂ is 585° C. Thus, the first bonding start temperature is specified to a temperature higher than 585° C., for example, 600° C. Moreover, the second bonding layer 140 comprises powdered glass including Bi₂O₃ and B₂O₃. The softening point of the powdered glass including Bi₂O₃ and B₂O₃ is 435° C. Thus, the second bonding start temperature is lower than 600° C. being the first bonding start temperature, and is specified to a temperature higher than 435° C. being the softening point, for example, 450° C.

According to the circuit substrate and the semiconductor module that include the bonding portion of the second embodiment that has been described above, when the second bonding layer 140 and other components are bonded at the second bonding start temperature, it is possible to suppress the excessive deformation of the first bonding layer 130 that has already been bonded to the semiconductor device 30 and the wiring substrate 10 at the time of the mounting of the semiconductor device due to the application of heat/pressure, and a reduction in the applied pressure to the second bonding layer 140. Hence, the manufacturing efficiency of the semiconductor module can be improved.

### C. Third Embodiment

### C1: Schematic Configuration of Semiconductor Module

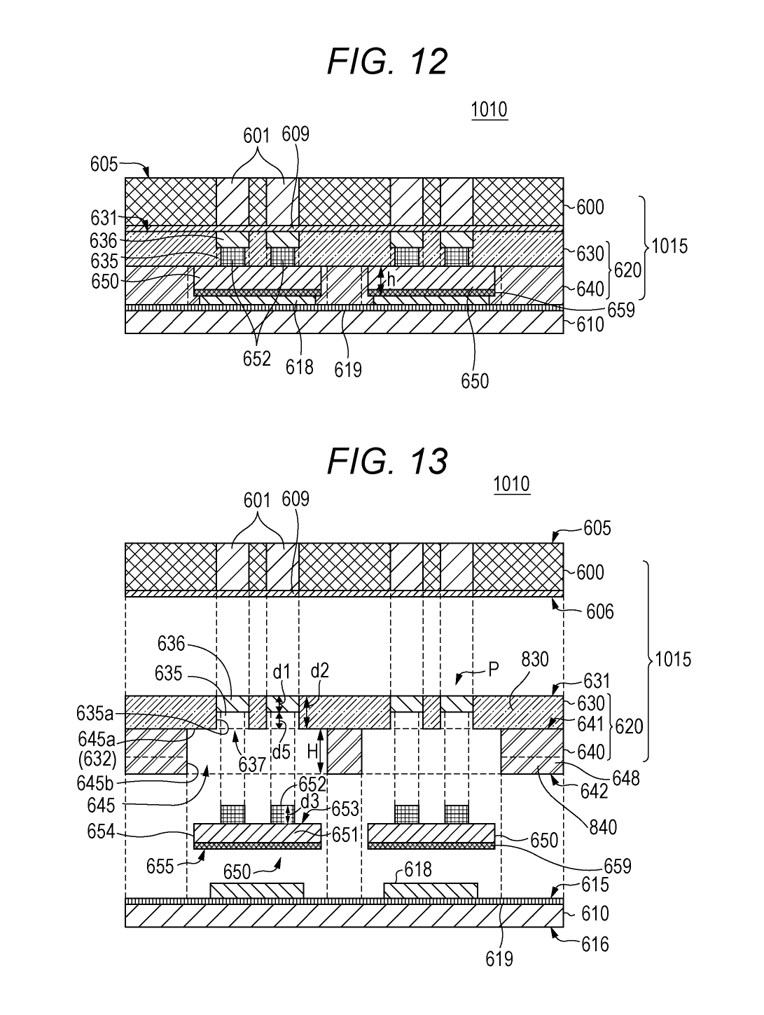

FIG. 12 is an illustrative cross-sectional view of a schematic configuration of a semiconductor power module 1010 in a third embodiment. FIG. 13 is an exploded sectional view of the semiconductor power module 1010 before bonding in the third embodiment. The semiconductor power module 1010 includes a first wiring substrate 600, a second wiring substrate 610, a bonding layer 620, and a semiconductor device 650. The first wiring substrate 600 and the bonding layer 620 constitute a circuit substrate 1015. Hereinafter, the first wiring substrate 600 and the second wiring substrate 610 are simply referred to also as the wiring substrate in the description.

The wiring substrates 600 and 610 comprise ceramic material, or glass-ceramic material where glass component is blended. For example, aluminum oxide (Al₂O₃), aluminum nitride, (AlN), and silicon nitride (Si₃N₄) can be used as the ceramic material.

The first wiring substrate 600 includes a first surface 605 on which electronic components such as a control circuit and a capacitor are mounted, a second surface 606 formed opposite to the first surface 605, an inner layer via hole 601 for electrically connecting between the first surface 605 and the second surface 606, and a pattern wiring 609, in addition to an electrode terminal for external connection (not illustrated) disposed on the first surface 605, and the like. The pattern wiring 609 is formed on the surface of the first wiring substrate 600, on the surface of an inner layer. In FIG. 12, pattern wiring formed in the inner layer of the first wiring substrate 600 is omitted.

The second wiring substrate 610 includes a first surface 615 on which the semiconductor device 650 is mounted, a second surface 616 on which parts such as a heat sink can be mounted, a metal bump 618 for establishing electrical continuity with the semiconductor device 650, and a pattern wiring 619. For example, a substrate that the circuit pattern wiring 619 is directly bonded on a ceramic plate, what is called, a DBC (Direct Bonding Copper) substrate is used for the second wiring substrate 610.

The semiconductor device 650 includes a casing 651, an electrode portion 652 formed on a front surface 653 of the casing 651, and a thin-film electrode layer 659 formed on a back surface 655 side of the casing 651. The electrode portion 652 includes an electrode pad, and a protruding metal bump formed on the electrode pad. The electrode portion 652 and the electrode layer 659 comprise, for example, gold (Au) as the main constituent. The bump of the electrode portion 652 may be formed by previously desposing at a desired position, a metal column processed in a bump shape, or may be formed by a method of transferring or printing paste having a metal species such as aluminum, copper, tin, and silver oxide as the main constituent onto the electrode pad by photolithography patterning or by screen printing. The semiconductor device 650 is electrically connected to the first wiring substrate 600 via a conductive bonding portion 636, the pattern wiring 609, and the inner layer via hole 601. Moreover, the semiconductor device 650 is electrically connected to the second wiring substrate 610 via the bump 618 and the pattern wiring 619 of the second wiring substrate 610. The electrode portion 652 corresponds to the “electrode portion” in the claims.

The bonding layer 620 is disposed on the second surface 606 side of the first wiring substrate 600, and is a thin insulating glass sheet including a first bonding layer 630 and a second bonding layer 640. The bonding layer 620 insulates the semiconductor device 650 from the wiring substrates 600 and 610. The detailed configuration of the bonding layer 620 will be described with reference to FIG. 13.

The first bonding layer 630 insulates between the first wiring substrate 600 and the semiconductor device 650. The first bonding layer 630 has insulating inorganic material as the main constituent, and includes an insulating glass sheet 830 comprising powdered glass that softens in the heating process at the time of the mounting of the semiconductor device, at least one through hole 635 formed at a position P of the glass sheet 830, corresponding to the inner layer via hole 601, and the conductive bonding portion 636 disposed in the through hole 635. In other words, the through hole 635 of the first bonding layer 630 is formed on a top side 645a of an opening portion 645 of the second bonding layer 640, which is described below. The powdered glass is formed as a multiphase of silicon oxide, zinc oxide, boron oxide, bismuth oxide, and the like, for example, ZnO—B₂O₃—SiO₂. The conductive bonding portion 636 is disposed in the through hole 635. Thus, a recess 637 is formed by the conductive bonding portion 636 and a side wall 635a of the through hole 635. The glass sheet 830 corresponds to the “first insulation layer” in the claims.

The conductive bonding portion 636 comprises conductive metal as the main constituent. For example, copper, silver, tin, and aluminum may be used as the conductive metal. If the semiconductor device 650 is disposed in the opening portion 645, the conductive bonding portion 636 establishes electrical continuity between the electrode portion 652 of the semiconductor device 650 and the first wiring substrate 600.

The recess 637 has a volume equal to or more than the volume of the electrode portion 652 of the semiconductor device 652, which is described below. As illustrated in FIG. 13, it is here assumed that d1 represents the thickness of the conductive bonding portion 636; d2 represents the thickness of the first bonding layer 630; d3 represents the height of the electrode portion 652; and d4 represents the tolerance of a variation in the height of the electrode portion 652 caused by warpage of the first wiring substrate 600. The height d3 of the electrode portion 652 is designed to be greater than the sum of d4 and the height d5=(the thickness d2 of the conductive bonding portion 636−the thickness d1 of the first bonding layer 630) of the recess 637, in other words, that the height d3 of the electrode portion 652 the height d5 of the recess 637=the tolerance d4 is satisfied. By designing in this manner, the conductive bonding portion 636 and the electrode portion 652 can be made sure to come into contact with each other, and the electrical continuity between the first wiring substrate 600 and the semiconductor device 650 can be secured. The reason is as described below.

Minute warpage and the like may occur upon the manufacture of the first wiring substrate 600. Therefore, if the height of the recess 637 in the thickness direction is made equal to the height d3 of the electrode portion 652 in the thickness direction, a gap may be created between a front end on the recess 637 side of the electrode portion 652 and the opposing recess 637 due to the influence of the minute warpage of the first wiring substrate 600. In other words, the electrical connection between the electrode portion 652 and the conductive bonding portion 636 cannot be secured. Hence, the height d3 of the electrode portion 652 in the thickness direction needs to take into consideration the height variation d4 of the first wiring substrate 600 in the thickness direction, in other words, the height d3 of the electrode portion 652>the height d5 of the recess 637 is satisfied to ensure electrical connection between the electrode portion 652 and the conductive bonding portion 636 when the semiconductor device 650 is disposed in the recess 637. Even if minute warpage and the like occur in the first wiring substrate 600, a variation in the height of the bonding surface equal to or less than “the height d3 of the electrode portion 652−the height d5 of the recess 637” is allowed.

The height d3 of the electrode portion 652≧the height d5 of the recess 637+the tolerance d4. Therefore, when the semiconductor device 650 is disposed in the opening portion 645 before the bonding of the first wiring substrate 600, the bonding layer 620, and the semiconductor device 650, a slight gap may be created between the front surface 653 of the semiconductor device 650 and the second bonding layer 640. However, as described above, the volume of the recess 637 is larger than the volume of the electrode portion 652. Therefore, the electrode portion 652 melts due to thermocompression at the time of bonding, and the entire electrode portion 652 is housed in the recess 637. Then, the height d3 of the electrode portion 652=the height d5 of the recess 637. The front surface 653 of the semiconductor device 650 comes into intimate contact with a second surface 632 of the first bonding layer 630.

Moreover, for convenience of description, the thickness d1 of the conductive bonding portion 636 and the thickness d2 of the first bonding layer 630 are simply expressed as the thickness in the above description. However, the first bonding layer 630 and the conductive bonding portion 636 may not be perfectly even in thickness and then variation may occur in thickness depending on the measuring position. Moreover, the electrode portion 652 of the semiconductor device 650 is not only formed in such a flat shape as is illustrated in the third embodiment, but may be formed in a spherical shape, for example by the mounting of a solder ball. Hence, d1 to d3 may be defined as follows: in other words, the thickness d1 of the conductive bonding portion 636 represents the maximum value of a distance at the conductive bonding portion 636 between the first surface 605 of the first wiring substrate 600 and a surface of the conductive bonding portion 636 on the semiconductor device 650 side. The thickness d2 of the first bonding layer 630 represents the maximum value of a distance between a surface of the first wiring substrate 600 on the first surface 605 side and a surface of the first bonding layer 630 on the semiconductor device 650 side. The height d3 of the electrode portion 652 represents the maximum value of the height of the electrode portion 652 in the lamination direction from the front surface 653 of the semiconductor device 650.

The second bonding layer 640 has insulating inorganic material as the main constituent, and includes an insulating glass sheet 840 comprising powdered glass that softens in the heating process at the time of the mounting of the semiconductor device, and the opening portion 645 for disposing the semiconductor device 650 therein, the opening portion 645 being formed in the glass sheet 840, communicating with the through hole 635, and being formed on the second surface 632 side different from a first surface 631 on which the first wiring substrate 600 is laminated. The powdered glass is formed as a multiphase of silicon oxide, zinc oxide, boron oxide, bismuth oxide, and the like, for example, ZnO—B₂O₃—SiO₂. When the semiconductor device 650 is disposed in the opening portion 645, the electrode portion 652 of the semiconductor device 650 is housed in the through hole 635, and electrical continuity is established between the electrode portion 652 and the first wiring substrate 600. The glass sheet 840 corresponds to the “second insulation layer” in the claims.

As illustrated in FIG. 13, the opening portion 645 is formed larger than the outside shape of the casing 651 of the semiconductor device 650 to create a gap of approximately several μm to several mm between a side surface 654 of the semiconductor device 650 and a side wall 645b of the opening portion 645. Consequently, it is possible to smoothly fit the semiconductor device 650 into the opening portion 645. Moreover, a depth H of the opening portion 645 in the lamination direction, corresponding to a distance between the top side 645a (the first surface 641) of the opening portion 645 and a second surface 642 of the second bonding layer 640, is larger than the distance h (FIG. 12) between the top side 645a of the opening portion 645 and the back surface 655 of the semiconductor device 650 in a state where the semiconductor device 650 is disposed in the opening portion 645.

When the semiconductor device 650 is disposed in the opening portion 645 of the second bonding layer 640, the surplus portion 648 corresponding to a difference Ah between the depth H of the opening portion 645 and the distance h between the top side 645a of the opening portion 645 and the back surface 655 of the semiconductor device 650 is produced in the bonding layer 620. When the second wiring substrate 610 is laminated and disposed on the back surface side of the semiconductor device 650, in other words, on the second surface 642 of the second bonding layer 640, and the wiring substrates 600 and 610, the semiconductor device 650, and the bonding layer 620 are heated and pressurized by diffusion bonding to be bonded into one piece, the surplus portion 648 deforms to fill the gap between the side wall 645b of the opening portion 645 and the side surface 654 of the semiconductor device 650 due to the deformation by heating and compression at the time of bonding. As a consequence, the second bonding layer 640 seals the vicinity of the side surface 654 of the semiconductor device 650. The insulating property between the wiring substrates 600 and 610 and the semiconductor device 650 is improved. Moreover, the gap formed between the first wiring substrate 600 and the second wiring substrate 610, and the bonding layer 620 due to the warpage at the time of manufacturing of the wiring substrates 600 and 610 is covered (filled) with the surplus portion 648. The bond strength between the first wiring substrate 600 and the second wiring substrate 610, and the bonding layer 620 is improved. The filling of the gap with the surplus portion 648 will be described in detail in the manufacturing method described below.

If the wiring substrates 600 and 610, the semiconductor device 650, and the bonding layer 620 are bonded into one piece, the first wiring substrate 600 and the semiconductor device 650 are electrically connected via the conductive bonding portion 636 and the electrode portion 652, and the semiconductor device 650 and the second wiring substrate 610 are electrically connected via the wiring layer 659 of the back surface 655 of the semiconductor device 650, and the bump 618 and the pattern wiring 619 of the second wiring substrate 610.

Moreover, the electrode portion 652 and the conductive bonding portion 636 deform to fill the space in the recess 637 due to the thermal deformation at the time of bonding. With the deformation, the semiconductor device 650 moves to the first wiring substrate 600 side, and the second surface 632 of the first bonding layer 630 (in other words, the top side 645a of the opening portion 645) and the front surface 653 of the semiconductor device 650 are bonded tightly.

It is preferred that the electrode portion 652 and the recess 637 be formed such that the volume of the electrode portion 652 is equal to the volume of the recess 637. However, if electrical connection is secured, the “volume of the recess 637>the volume of the electrode portion 652” is acceptable.

### C2. Manufacturing Method

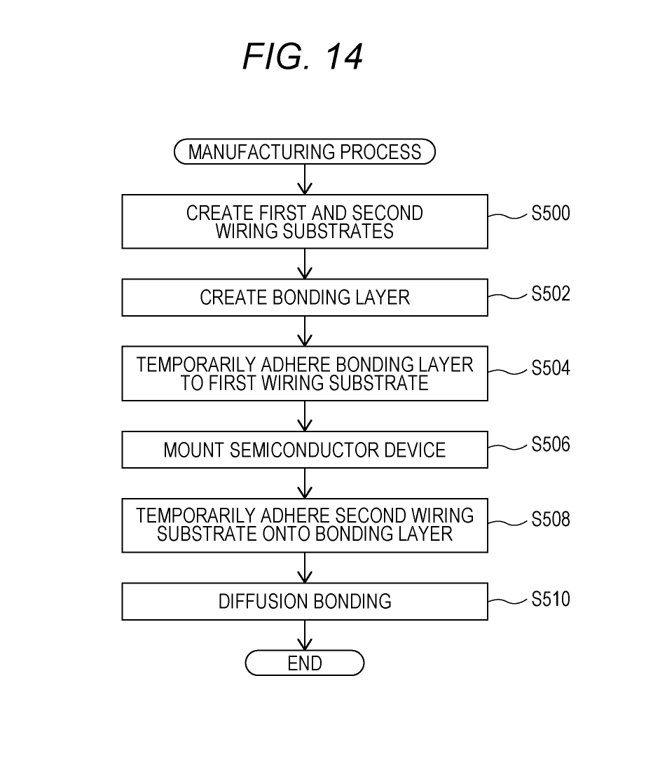

A method for manufacturing the semiconductor power module 1010 will be described using FIGS. 14 to 21B. FIG. 14 is a process drawing illustrating the method for manufacturing the semiconductor power module 1010 in the third embodiment.

In Step S500, the wiring substrate 600 including the inner layer via hole 601 and the pattern wiring 609, and the second wiring substrate 610 including the pattern wiring 619 are created.

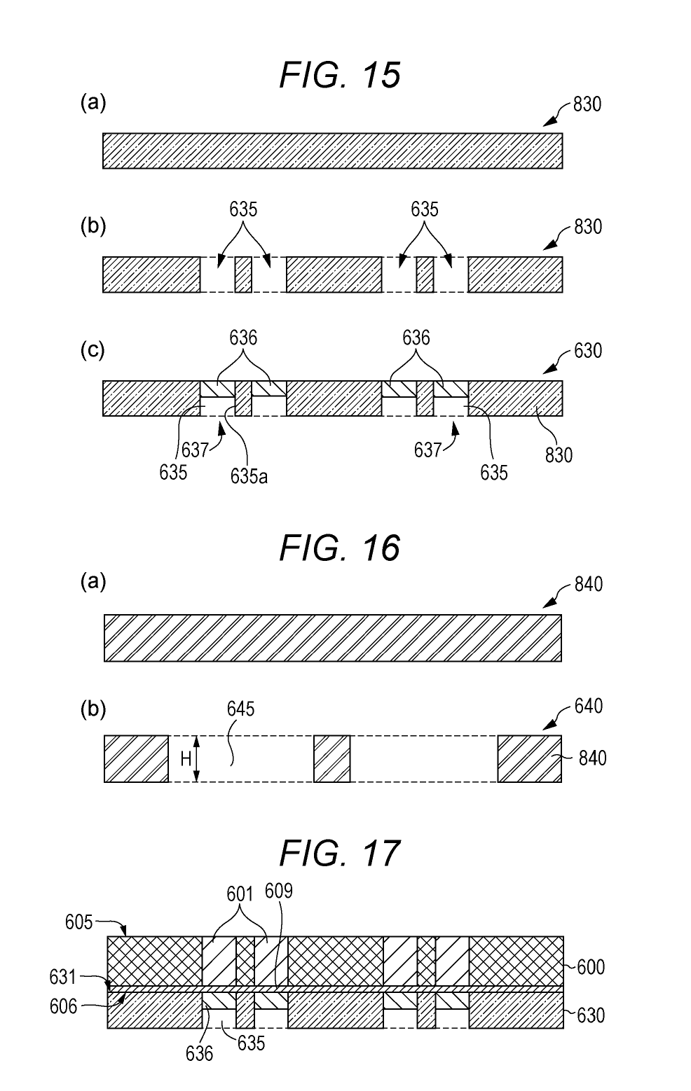

In Step S502, the first bonding layer 630 and the second bonding layer 640, which constitute the bonding layer 620, are created. FIGS. 15A to 15C are explanatory diagrams illustrating the creation of the first bonding layer 630. FIGS. 16A and 16B are explanatory diagrams illustrating the creation of the second bonding layer 640.

The glass sheet 830 (FIG. 15A) included in the first bonding layer 630 and the glass sheet 840 (FIG. 16A) included in the second bonding layer 640 are created. Specifically, the slurry formed from powdered glass that softens by the application of heat in a diffusion bonding process, which is described below, and an organic binding agent having a thermal decomposition property with a solvent such as an organic solvent or water is molded in a sheet shape by sheet casting by a doctor blade method, or a method by extrusion molding or the like. The slurry is then dried to create the glass sheets 830 and 840. Powdered glass formed as a mixed phase of silicon oxide, zinc oxide, boron oxide, lead oxide, bismuth oxide, and the like, for example, ZnO—B₂O₃—SiO₂, can be used as the powdered glass. Moreover, ceramic powder material such as alumina may be blended as a filler in the first bonding layer 630 and the second bonding layer 640.

As illustrated in FIG. 15B, machining such as laser or microcomputer punching is performed at a position P corresponding to the inner layer via hole 601 of the first wiring substrate 600 on the created glass sheet 830 included in the first bonding layer 630. Thus, the through hole 635 is formed.

Next, as illustrated in FIG. 15C, the conductive bonding portion 636 is formed in the through hole 635. Specifically, paste included in the conductive bonding portion 636 is partially filled in the through hole 635 by screen printing. The paste has metal as the main constituent, and is formed by blending a metal species that melts by diffusion bonding, which is described below, such as aluminum, silver oxide, copper, nano metal, and solder alloy, and an organic binding agent having a thermal decomposition property with a solvent such as an organic solvent or water. The filling of the paste is not limited to screen printing. However, for example, a method such as ejection by a dispenser may be used. With the formation of the conductive bonding portion 636 in the through hole 635, the recess 637 is formed. In this manner, the first bonding layer 630 is formed.

Moreover, as illustrated in FIG. 16B, machining such as laser or microcomputer punching is performed at a position where the semiconductor device 650 is mounted on the glass sheet 840 included in the second bonding layer 640. Thus, the opening portion 645 is formed. At this point, the opening portion 645 is formed larger than the outside shape of the casing 651 of the semiconductor device 650 to create a gap of approximately several μm to several mm between the side surface 654 of the semiconductor device 650 and the side wall 645b of the opening portion 645. Moreover, a depth H of the opening portion 645 in the lamination direction is formed to be larger than the distance h between the first surface 641 of the second bonding layer 640 and the back surface 655 of the semiconductor device 650 in the state where the semiconductor device 650 is disposed in the opening portion 645. In other words, the thickness of the second bonding layer 640 is formed to be larger than the distance h between the first surface 641 of the second bonding layer 640 and the back surface 655 of the semiconductor device 650. In this manner, the second bonding layer 640 is formed.

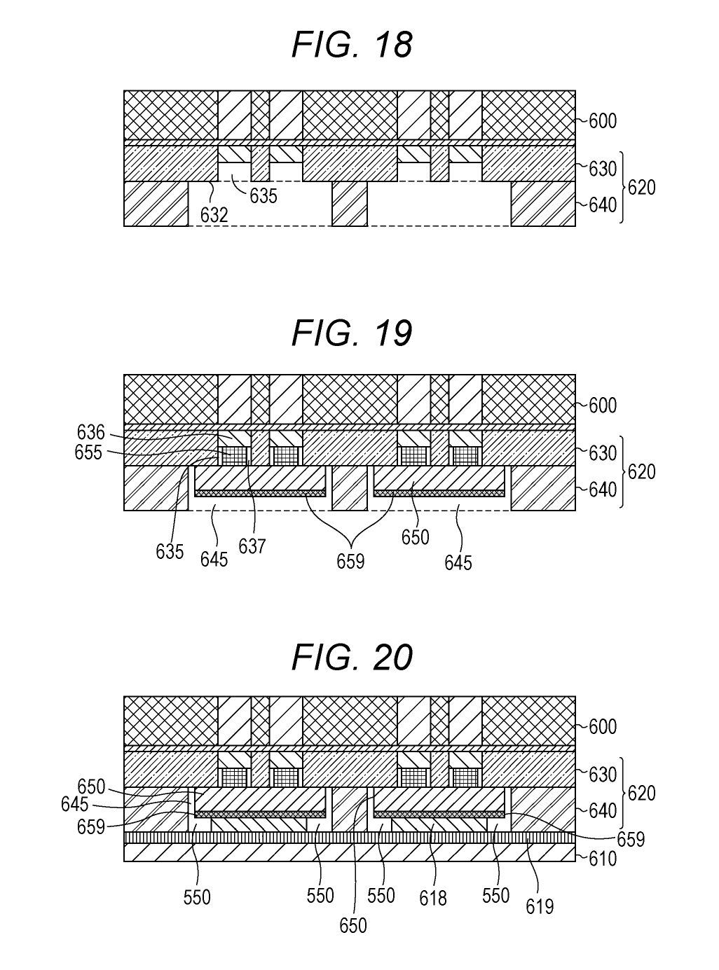

In Step S504, the first wiring substrate 600 and the bonding layer 620 are temporarily adhered. FIG. 17 is an explanatory diagram illustrating temporary adhesion of the first wiring substrate 600 and the first bonding layer 630 in the third embodiment. FIG. 18 is an explanatory diagram illustrating the formation of the bonding layer 620 in the third embodiment. As illustrated in FIG. 17, in order to enable electrical continuity to be established between the conductive bonding portion 636 of the first bonding layer 630 and the inner layer via hole 601 of the first wiring substrate 600, the conductive bonding portion 636 is opposed to the inner layer via hole 601, and the first wiring substrate 600 is laminated on the first surface 631 of the first bonding layer 630 (in other words, the first bonding layer 630 is laminated on the second surface 606 of the first wiring substrate 600) to temporarily adhere them by the adhesive strength of the organic binding agent included in the first bonding layer 630. The organic adhesive is decomposed and removed in the thermal process.

Next, as illustrated in FIG. 18, the second bonding layer 640 is positioned and laminated on the second surface 632 of the first bonding layer 630 to temporarily adhere the first bonding layer 630 and the second bonding layer 640 by the adhesive strength of the organic binding agent included in the first bonding layer 630 and the second bonding layer 640. The bonding layer 620 is then formed. The positioning of the first bonding layer 630 and the second bonding layer 640 includes positioning to match the through hole 635 and the opening portion 645 with the mounting of the semiconductor device 650, in other words, to cause the through hole 635 and the opening portion 645 to communicate with each other, and to house the electrode portion 652 in the recess 637 when the semiconductor device 650 is disposed in the opening portion 645.

In Step S506, the semiconductor device 650 is mounted in the opening portion 645 of the bonding layer 620. FIG. 19 is an explanatory diagram illustrating the mounting state of the semiconductor device 650 in the third embodiment. As illustrated in FIG. 19, the semiconductor device 650 is disposed in the opening portion 645. Thus, the electrode portion 652 of the semiconductor device 650 is housed in the through hole 635 of the bonding layer 620 and establishes electrical continuity with the conductive bonding portion 636. The electrode portion 652 is previously formed to have a volume equal to or less than the volume of the recess 637. Specifically, a metal bump comprising a metal species that melts in the heating process of Step S510, which is described below, such as aluminum, silver oxide, copper, tin, nano metal, and solder alloy, is disposed on the electrode portion 652. Metal formed into a ball may be disposed at a desired position to form the bump by a ball mounting method that shapes the metal into a column by a heating process, or a metal bump may be formed at a desired position by a method of transferring metal to form a bump at a corresponding position of the semiconductor device 650, or a method of printing paste having the already described metal species as the main constituent by screen printing, or by plating after performing masking by photolithography patterning.

In Step S508, the bonding layer 620 and the second wiring substrate 610 are temporarily adhered in the state where the semiconductor device 650 is disposed in the opening portion 645. FIG. 20 is an explanatory diagram illustrating temporary adhesion of the second wiring substrate 610 and the bonding layer 620 in the third embodiment. As illustrated in FIG. 20, the bonding layer 620 and the second wiring substrate 610 are positioned such that the bump 618 of the second wiring substrate 610 is opposed to the wiring layer 659 on the back surface 655 of the semiconductor device 650 to temporarily adhere them by the adhesive strength of the organic binding agent included in the bonding layer 620. The organic adhesive is decomposed and removed in the thermal process.

The wiring substrates 600 and 610, the bonding layer 620, and the semiconductor device 650 are bonded by diffusion bonding to manufacture a semiconductor power module (Step S510). Specifically, the wiring substrates 600 and 610, the bonding layer 620, and the semiconductor device 650 are pressurized in the lamination direction, and the bonding layer 620, the conductive bonding portion 636, the electrode portion 652, and the bump 618 are heated to a temperature of thermal fusion bonding. By the application of pressure and heat, atomic diffusion occurs at the bonding surface between the first wiring substrate 600 and the bonding layer 620 and the bonding surface between the bonding layer 620 and the second wiring substrate 610 to bond the wiring substrates 600 and 610 and the bonding layer 620. Moreover, both materials of the electrode portion 652 of the semiconductor device 650 and the conductive bonding portion 636, and the wiring layer 659 on the back surface 655 of the semiconductor device 650 and the bump 618 melt by the application of heat, and are bonded.

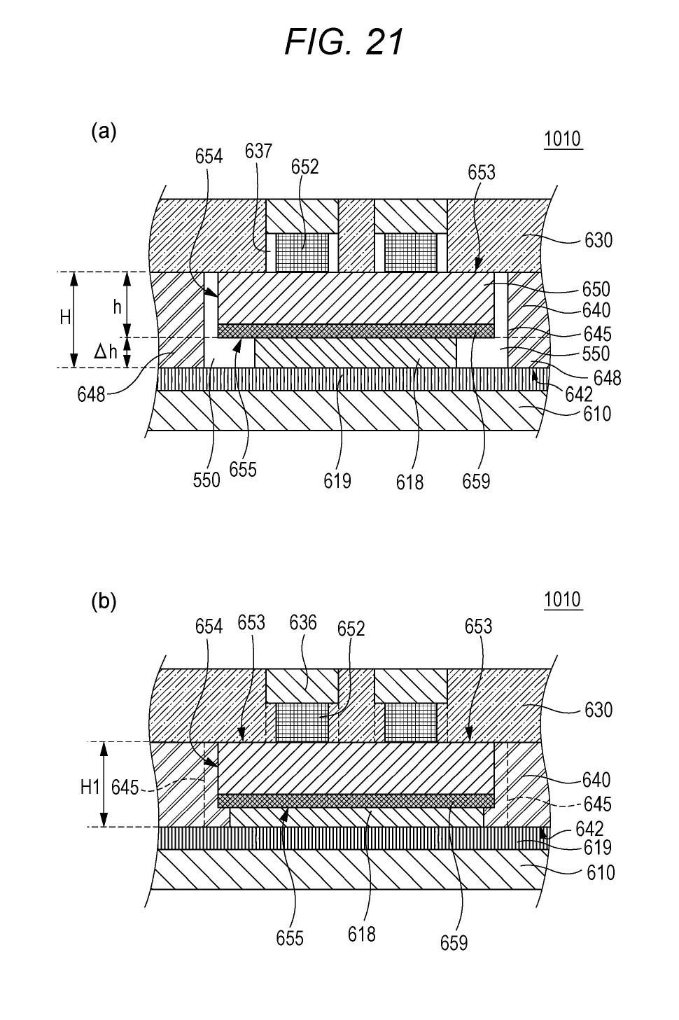

FIGS. 21A and 21B are explanatory diagrams illustrating the filling of a gap 550 portion by the surplus portion 648 upon diffusion bonding. FIG. 21A illustrates the enlarged mounting location of the semiconductor device 650 before the thermocompression bonding. FIG. 21B illustrates the enlarged mounting location of the semiconductor device 650 after the thermocompression bonding.

As illustrated in FIG. 21A, in the state where the semiconductor device 650 is housed in the opening portion 645, the semiconductor device 650 is mounted such that the back surface 655 to come into contact with the second wiring substrate 610 is in a position located inside the opening portion 645 by Δh (depth H−distance h) from the end of the opening portion 645, in other words, the second surface 642 of the second bonding layer 640. Therefore, the surplus portion 648 equivalent to the thickness Ah exists in other parts of the second bonding layer 640, excluding the opening portion 645. The thickness Ah is specified such that the volume of the surplus portion 648 is equal to or more than the volume of the gap 550.

As illustrated in FIG. 21B, when the wiring substrates 600 and 610, the bonding layer 620, and the semiconductor device 650 are heated in diffusion bonding, and pressed in the lamination direction, the second wiring substrate 610 is pressed against the semiconductor device 650 and the second bonding layer 640. At this point, the temperature is higher than the softening temperature of the glass composition being the base material of the second bonding layer 640 and then the second bonding layer 640 is rich in fluidity, and the gap 550 between the side wall 645b of the opening portion 645 and the semiconductor device 650 is filled with the second bonding layer 640. Consequently, the outer surfaces (the front surface 653 and the side surface 654) of the casing 651 of the semiconductor device 650 are covered with the insulative second bonding layer 640. Thus, the insulating property between the electrode portion 652 of the semiconductor device 650 and the pattern wiring 619 of the second wiring substrate 610 is improved to prevent discharge on the creepage surface of the semiconductor device 650.

With the filling of the gap 550, the thickness of the second bonding layer 640 becomes H1 that is slightly thinner than the thickness H before bonding. With the thinning of the second bonding layer 640, the bump 618 of the second wiring substrate 610, which is melting, spreads in the horizontal direction (the direction substantially orthogonal to the pressing direction), and its thickness becomes slightly thinner. The bump 618 flows in this manner. Thus, the bond strength between the second wiring substrate 610, and the second bonding layer 640 and the semiconductor device 650 can be secured.

The thermal fusion bonding temperature of the bonding layer 620, the conductive bonding portion 636, the electrode portion 652, and the bump 618 may be, for example, the melting point of metal included in the conductive bonding portion 636, the electrode portion 652, and the bump 618, or the softening point of the glass composition of the material of the bonding layer 620, whichever is higher. In the third embodiment, aluminum having a melting point of 660° C. is used as the material of the conductive bonding portion 636, the electrode portion 652, and the bump 618. A ZnO—B₂O₃—SiO₂ glass having a softening point of 640° C. is used as the material of the bonding layer 620. Both materials are heated for five minutes at a thermal fusion bonding temperature of 670° C. Moreover, in the third embodiment, the wiring substrates 600 and 610, the bonding layer 620, and the semiconductor device 650 are pressurized at a pressure of approximately 100 kPa. As described above, the semiconductor power module 1010 of the third embodiment illustrated in FIG. 12 is created.

According to the circuit substrate 1015, the semiconductor power module 1010, and the method for manufacturing the semiconductor power module 1010 of the third embodiment described above, the opening portion 645 of the bonding layer 620 is formed such that the depth of the opening portion 645 is larger than the distance h between the top side 645a of the opening portion 645 and the back surface 655 of the semiconductor device 650. Therefore, in the bonding layer 620, it is possible to produce the surplus portion 648 corresponding to the difference Ah between the depth H of the opening portion 645 and the distance h between the top side 645a of the opening portion 645 and the back surface 655 of the semiconductor device 650. Hence, if the gap 550 is created between the wiring substrate 600, 610, and the bonding layer 620, and between the side wall 645b of the opening portion 645 of the bonding layer 620 and the side surface 654 of the semiconductor device 650, the gap 550 can be covered (filled) by the surplus portion 648. Therefore, the insulating property between the semiconductor device 650 and the wiring substrates 600 and 610, more specifically, the insulating property between the electrode portion 652 of the semiconductor device 650 and the pattern wiring 619 of the second wiring substrate 610 is improved. Thus, it is possible to promote the prevention of discharge on the creepage surface of the semiconductor device 650. Moreover, it is possible to promote the prevention of damage to the semiconductor device 650 due to the existence of the gap around the semiconductor device. Moreover, also when a gap is created between the wiring substrates 600 and 610 and the bonding layer 620 due to the warpage of the wiring substrates 600 and 610 occurring during manufacture, the gap can be covered (filled) with the surplus member 648. Therefore, the bond strength between the wiring substrates 600 and 610 and the bonding layer 620 can be improved.

Moreover, according to the circuit substrate 1015, the semiconductor power module 1010, and the method for manufacturing the semiconductor power module 1010 of the third embodiment, the through hole 635 is formed to have a volume equal to or more than a summation of the volume of the conductive bonding portion 636 and the volume of the electrode portion 652 of the semiconductor device 650, and the opening portion 645 is formed such that the depth H is larger than the thickness of the semiconductor device 650. Therefore, upon the mounting of the semiconductor device 650 in the opening portion 645, the entire electrode portion 652 is housed in the through hole 635 to ensure contact between the front surface 653 of the semiconductor device 650 and the top side 645a of the opening portion 645. Hence, it is possible to secure the insulating property between the front surface 653 of the semiconductor device 650 and the bonding layer 620 and prevent discharge on the creepage surface of the semiconductor device 650 while filling with the bonding layer 620 the gap formed between the side surface 654 of the semiconductor device 650 and the side wall 645b of the opening portion 645.

Moreover, according to the circuit substrate 1015, the semiconductor power module 1010, and the method for manufacturing the semiconductor power module 1010 of the third embodiment, the inner wall of the opening portion is formed in a flat shape in the lamination direction. Therefore, the opening portion can be manufactured by a simple method such as punching.

### D. Fourth Embodiment

In a fourth embodiment, the shape of an opening portion of a bonding layer where the semiconductor device 650 is mounted is set to be a tapered shape that expands the diameter from the first wiring substrate 600 toward the second wiring substrate 610. The fourth embodiment has similar configurations, functions, and operations to the third embodiment other than the shape of the opening portion of the bonding layer. Thus, a description will be given with the reference numerals of the third embodiment. Moreover, a semiconductor power module 1020 of the fourth embodiment is manufactured by a similar manufacturing process to the semiconductor power module 1010 of the third embodiment.

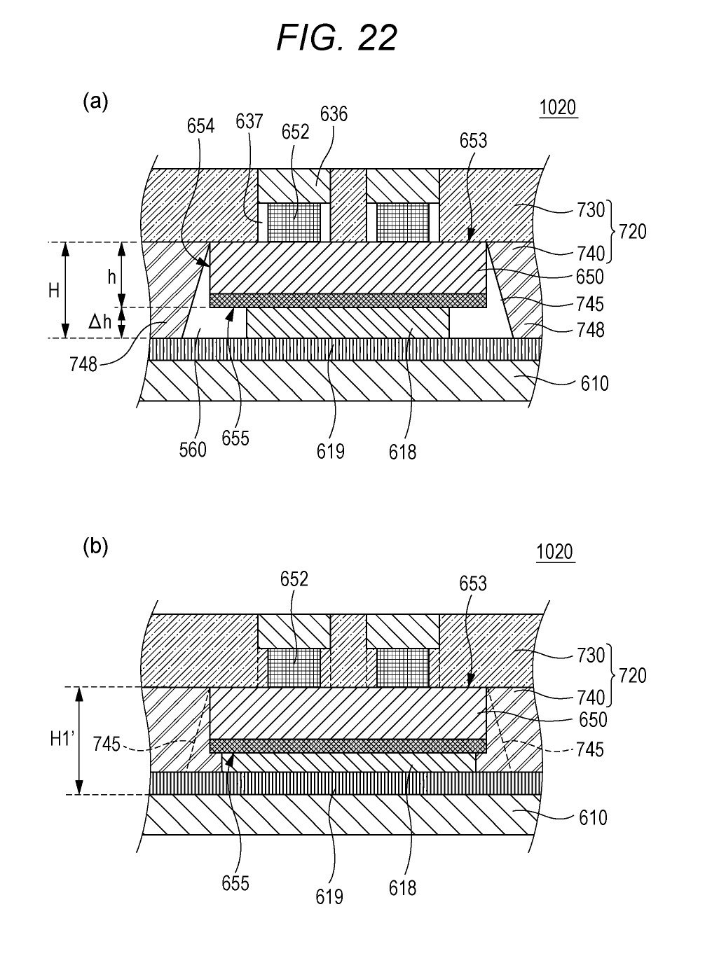

FIGS. 22A and 22B are explanatory diagrams illustrating the filling of a gap portion between a bonding layer 720 and the semiconductor device 650 in the fourth embodiment. FIG. 22A illustrates the enlarged mounting location of the semiconductor device 650 before the thermocompression bonding. FIG. 22B illustrates the enlarged mounting location of the semiconductor device 650 after the thermocompression bonding. The bonding layer 720 includes a first bonding layer 730 and a second bonding layer 740. As illustrated in FIGS. 22A and 22B, in the fourth embodiment, an opening portion 745 of the second bonding layer 740 of the bonding layer 720 is formed in a tapered shape that expands the diameter from the first wiring substrate 600 toward the second wiring substrate 610. A depth H of the opening portion 745 is the same as the depth H of the opening portion 645 of the third embodiment.

As illustrated in FIG. 22A, in a state where the semiconductor device 650 is housed in the opening portion 745, the semiconductor device 650 is mounted such that the back surface 655 to come into contact with the second wiring substrate 610 is in a position located inside the opening portion 745 by Δh (depth H−distance h) from the end of the opening portion 745, in other words, a second surface 742 of the second bonding layer 740. Therefore, a surplus portion 748 equivalent to the thickness Ah exists in other parts of the second bonding layer 740, excluding the opening portion 745.

As illustrated in FIG. 22B, when the wiring substrates 600 and 610, the bonding layer 720, and the semiconductor device 650 are heated in diffusion bonding, and pressed in the lamination direction, the second wiring substrate 610 is pressed against the semiconductor device 650 and the second bonding layer 740. At this point, the temperature is higher than the softening temperature of a glass composition being the base material of the second bonding layer 740 and then the second bonding layer 740 is rich in fluidity, and a gap 560 between a side wall 745b of the opening portion 745 and the semiconductor device 650 is filled with the second bonding layer 740. In FIG. 22B, the opening portion 745 before being filled is represented by the broken line. Consequently, the surface of the casing 651 of the semiconductor device 650 is covered with the insulative second bonding layer 740. Thus, the insulating property between the electrode portion 652 of the semiconductor device 650 and the pattern wiring 619 of the second wiring substrate 610 is improved to prevent discharge on the creepage surface of the semiconductor device 650.

With the filling of the gap 560, the thickness of the second bonding layer 740 becomes H1′ that is slightly thinner than the thickness H before bonding. With the thinning of the second bonding layer 740, the bump 618 of the second wiring substrate 610, which is melting, spreads in the horizontal direction (the direction substantially orthogonal to the pressing direction), and its thickness becomes slightly thinner. The bump 618 flows in this manner. Thus, the bond strength between the second wiring substrate 610, and the second bonding layer 740 and the semiconductor device 650 can be secured.

According to the semiconductor power module 1020 of the fourth embodiment described above, the opening portion is formed in a tapered shape. Therefore, pressure is applied in the lamination direction upon bonding of the bonding layer and the wiring substrate. Thus, the filling efficiency of the gap can be improved and the generation of bubbles can be suppressed.

### E. Modification

(1) In the above embodiments, the powdered glass comprising Na₂O₃, B₂O₃, and SiO₂, and the powdered glass comprising Bi₂O₃ and B₂O₃ are described as examples of the material included in the bonding layer. However, various materials such as powdered glass comprising Na₂O₃, ZnO, and B₂O₃ (the temperature to start a sintering reaction: 460° C., the melting point: 560° C.) may be used.
(2) In the first and second embodiments, the glass sheets of the first bonding layer 130 and the second bonding layer 140 may be formed by laminating a plurality of glass sheets. Consequently, it is especially effective as a method for creating the bonding layer in such points as that the shape (for example, the tapered shape in the fourth embodiment) of the opening portion 145 can be flexibly changed in size. In other words, the first and second bonding layers include a plurality of layers, which enables the first and second bonding layers to have a slant function. Thus, more detailed control can be performed. For example, in the third embodiment, the conductive bonding portion 636 is filled in a part of the through hole 635 to form the recess 637 in the first bonding layer 630. However, it may be set such that the first bonding layer includes a layer having a thickness corresponding to the thickness of the conductive bonding portion 636 in the lamination direction while the second bonding layer includes two layers of a layer having a thickness corresponding to the thickness of the recess 637, and the second bonding layer 640 in the third embodiment. If the conductive bonding portion 636 is filled in the through hole 635 of the first bonding layer 630 of the third embodiment to form the recess 637, the insulating property may be reduced due to the attachment of a conductive paste included in the conductive bonding portion 636 to the wall surface of the through hole 635, or the leak of the paste upon the filling of the paste. On the other hand, as in the modification, the second bonding layer includes a plurality of layers to make it possible to suppress the attachment and leak of the conductive paste and to suppress a reduction in insulating property.
(3) In the first embodiment, the first bonding layer 130 and the second bonding layer 140 are created (a state where the conductive bonding portion 136 is filled in the through hole 135), and then temporarily adhered to the first wiring substrate 100. However, it may be set such that after the glass sheets 330 and 340 included in the first bonding layer 130 and the second bonding layer 140 are created, the glass sheet 330 is temporarily adhered to the first wiring substrate 100, and the glass sheet 340 is temporarily adhered to the glass sheet 330, the opening portion 145 and the through hole 135 are formed by a laser or the like and the conductive bonding portion 136 is filled in the through hole 135. In other words, the order of the formation of the bonding layer 120 including the formation of the through hole 135 and the opening portion 145, and the temporary adhesion of the bonding layer 120 and the wiring substrate 10 can be any order. The same shall apply to the third embodiment.
(4) In the third embodiment, the bonding layer 620 has a multi-layer structure formed by laminating a plurality of glass sheets, but may be a single layer structure. In this case, for example, a method for forming the through hole 635 and the opening portion 645 by performing a process such as laser irradiation and punching on one glass sheet can be used.
(5) In the third and fourth embodiments, the first bonding start temperature of the first bonding layer and the second bonding start temperature of the second bonding layer may be different as in the first and second embodiments.

The present invention is not limited to the above embodiments, embodiments and modification, but can be realized by various configurations without departing from its purport. For example, the technical features in the embodiments, embodiments, and modification corresponding to the technical features in the modes described in the disclosure of the invention can be replaced and combined as appropriate to solve a part or all of the above problems or to achieve a part of all of the above effects. Moreover, the technical features can be deleted as appropriate unless described as an indispensable one in the description.

### DESCRIPTION OF REFERENCE SIGNS

10 Wiring substrate
11 Ceramic layer
12 Control circuit wiring
13 Main power straight via
14 Upper surface wiring
15 Lower surface wiring
16 First insulation bonding portion
17 Screw housing portion
17a Screw housing portion
18 Heat dissipation layer
19 Screw
20 Bonding portion
30 Semiconductor device
31 Casing
32 Electrode portion
34 Side surface
39 Electrode wiring layer
40 Insulating substrate
45 Electrode wiring layer
46 Electrode wiring
47 Third insulation bonding portion
50 Heat sink
51 Fin
52 Housing
53 Screw hole
60 Upper jig
61 Lower jig
70 Circuit substrate
80 Heat dissipation substrate
100 Semiconductor module
120 Bonding layer
130 First bonding layer
131 First surface
132 Second surface
135 Through hole
135a Side wall
136 Conductive bonding portion
137 Recess
140 Second bonding layer
145 Opening portion
145a Top side
145b Side wall
200 Low heat generating component
330 Glass sheet
340 Glass sheet
430 Glass sheet
500 Gap
510 Gap
550 Gap
560 Gap
600 Wiring substrate
601 Inner layer via hole
605 First surface
606 Second surface
609 Pattern wiring
610 Second wiring substrate
615 First surface
616 Second surface
618 Bump
619 Pattern wiring
620 Bonding layer
630 First bonding layer
631 First surface
632 Second surface
635 Through hole
635a Side wall
636 Conductive bonding portion
637 Recess
640 Second bonding layer
641 First surface
642 Second surface
645 Opening portion
645a Top side
645b Side wall
648 Surplus portion
650 Semiconductor device
651 Casing
652 Electrode portion
653 Front surface
654 Side surface
655 Back surface
659 Electrode wiring layer
720 Bonding layer
730 First bonding layer
740 Second bonding layer
742 Second surface
745 Opening portion
745b Side wall
748 Surplus portion
830 Glass sheet
840 Glass sheet
1010 Semiconductor power module
1015 Circuit substrate
1020 Semiconductor power module

What is claimed is:

1. A semiconductor module comprising:
a wiring substrate where a via and a interconnecting pattern are formed;
a semiconductor device disposed on a first surface side of the wiring substrate; and
a bonding portion, disposed on the first surface of the wiring substrate, for bonding the semiconductor device and the wiring substrate, the bonding portion including a first bonding layer disposed on the wiring substrate side, and a second bonding layer disposed on the semiconductor device side, wherein
the first bonding layer includes
a first insulation layer having inorganic material as a main constituent,
at least one through hole formed in an area of the first insulation layer corresponding to the via, and
a conductive bonding portion, disposed in the through hole, for establishing electrical continuity between an electrode portion formed on the semiconductor device and the wiring substrate, and
has a first bonding start temperature being a temperature to start bonding to the wiring substrate; and
the second bonding layer includes
a second insulation layer having inorganic material as a main constituent, and
an opening portion communicating with the through hole and configured to dispose the semiconductor device therein, and
has a second bonding start temperature being a temperature to start bonding to the semiconductor device, the temperature being different from the first bonding start temperature.

2. The semiconductor module according to claim 1, wherein the first bonding start temperature is lower than the second bonding start temperature.

3. The semiconductor module according to claim 1, wherein the first bonding start temperature is higher than the second bonding start temperature.

4. A circuit substrate comprising:
a wiring substrate where a via and a interconnecting pattern are formed; and
a bonding portion, disposed on a first surface of the wiring substrate, for bonding a semiconductor device and the wiring substrate, the bonding portion including a first bonding layer disposed on the wiring substrate side, and a second bonding layer disposed on the semiconductor device side, wherein
the first bonding layer includes
a first insulation layer having inorganic material as a main constituent,
at least one through hole formed in an area of the first insulation layer corresponding to the via, and
a conductive bonding portion, disposed in the through hole, for establishing electrical continuity between an electrode portion formed on the semiconductor device and the wiring substrate, and
has a first bonding start temperature being a temperature to start bonding to the wiring substrate; and
the second bonding layer includes
a second insulation layer having inorganic material as a main constituent, and
an opening portion communicating with the through hole and configured to dispose the semiconductor device therein, and
has a second bonding start temperature being a temperature to start bonding to the semiconductor device, the temperature being different from the first bonding start temperature.

5. The circuit substrate according to claim 4, wherein the first bonding start temperature is lower than the second bonding start temperature.

6. The circuit substrate according to claim 4, wherein the first bonding start temperature is higher than the second bonding start temperature.

7. The circuit substrate according to claim 4, wherein when the semiconductor device is disposed in the opening portion, a depth of the opening portion is larger than a distance between a top side of the opening portion and an underside of the semiconductor device.

8. The circuit substrate according to claim 7, wherein
the through hole is formed to have a volume equal to or more than a summation of the volume of the conductive bonding portion and the volume of the electrode portion of the semiconductor device, and
the depth of the opening portion is larger than a thickness of a casing of the semiconductor device.

9. The circuit substrate according to claim 7, wherein the volume of a surplus portion of the bonding portion corresponding to a difference between the depth of the opening portion and a distance between the top side of the opening portion and the underside of the semiconductor device is equal to or more than the volume of a gap formed between the semiconductor device and the opening portion.

10. The circuit substrate according to claim 7, wherein the opening portion is formed in a tapered shape.

11. The circuit substrate according to claim 7, wherein an inner wall of the opening portion is formed in a flat shape in a lamination direction.
